(19) United States
(12) Patent Application Publication
(10) Pub. No.: US 2024/0018442 A1
(43) Pub. Date: Jan. 18, 2024

(54) CLEANING LIQUID FOR SEMICONDUCTOR SUBSTRATE AND CLEANING METHOD FOR SEMICONDUCTOR SUBSTRATE

(71) Applicant: FUJIFILM Corporation, Tokyo (JP)

(72) Inventors: Naoko OUCHI, Haibara-gun (JP); Tetsuya Kamimura, Haibara-gun (JP); Shimpei Yamada, Haibara-gun (JP); Naotsugu Muro, Haibara-gun (JP)

(73) Assignee: FUJIFILM Corporation, Tokyo (JP)

(21) Appl. No.: 18/473,501

(22) Filed: Sep. 25, 2023

Related U.S. Application Data
(63) Continuation of application No. PCT/JP2022/009943, filed on Mar. 8, 2022.

(30) Foreign Application Priority Data
Mar. 26, 2021 (JP) 2021-052648

(51) Int. Cl. C11D 1/62; C11D 11/00; C11D 3/00; C11D 3/28; C11D 3/30; C11D 3/20; H01L 21/02

(52) U.S. Cl. CPC C11D 1/62; C11D 11/0047; C11D 3/0073; C11D 3/28; C11D 3/30; C11D 3/2082; C11D 3/2086; H01L 21/02074

(57) ABSTRACT

An object of the present invention is to provide a cleaning liquid for a semiconductor substrate, which is excellent in cleaning performance of organic impurities, and a cleaning method for a semiconductor substrate. The cleaning liquid for a semiconductor substrate according to the present invention is a cleaning liquid for a semiconductor substrate used for cleaning a semiconductor substrate, and includes a compound represented by Formula (A).

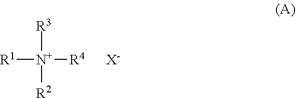

### CROSS-REFERENCE TO RELATED APPLICATIONS

This application is a Continuation of PCT International Application No. PCT/JP2022/009943 filed on Mar. 8, 2022, which claims priority under 35 U.S.C. § 119(a) to Japanese Patent Application No. 2021-052648 filed on Mar. 26, 2021. The above applications are hereby expressly incorporated by reference, in their entirety, into the present application.

### BACKGROUND OF THE INVENTION

### 1. Field of the Invention

The present invention relates to a cleaning liquid for a semiconductor substrate and a cleaning method for a semiconductor substrate.

### 2. Description of the Related Art

Semiconductor elements such as a charge-coupled device (CCD) and a memory are manufactured by forming a fine electronic circuit pattern on a substrate by using a photolithographic technique. Specifically, semiconductor elements are manufactured by forming a resist film on a laminate that has a metal film serving as a wiring line material, an etching stop layer, and an interlayer insulating layer on a substrate, and carrying out a photolithography step and a dry etching step (for example, a plasma etching treatment).

In the manufacture of a semiconductor element, a chemical mechanical polishing (CMP) treatment in which a surface of a semiconductor substrate having a metal wiring line film, a barrier metal, an insulating film, or the like is flattened using a polishing slurry including polishing fine particles (for example, silica and alumina) may be carried out. In a CMP treatment, polishing fine particles to be used in the CMP treatment, a polished wiring line metal film, and/or a metal component derived from a barrier metal and the like easily remain on a surface of a semiconductor substrate after polishing.

Since these residues can short-circuit wiring lines and affect the electrical characteristics of a semiconductor, a cleaning step in which these residues are removed from the surface of the semiconductor substrate is generally carried out.

As a cleaning liquid that is used in the cleaning step, for example, JP2012-251026A discloses a cleaning agent for a semiconductor, which contains a quaternary ammonium hydroxide or the like.

### SUMMARY OF THE INVENTION

A cleaning liquid for a semiconductor substrate is required to have excellent cleaning performance, and in particular, in recent years, there is a demand to be excellent in cleaning performance of organic impurities.

For example, as a result of examining the cleaning performance of the cleaning liquid for a semiconductor substrate described in JP2012-251026A with respect to a semiconductor substrate including a metal film subjected to a chemical and/or physical treatment (for example, a CMP treatment and/or an etching treatment, or the like), the inventors of the present invention found that there is room for improvement in the cleaning performance of organic impurities.

More specifically, it was found that in a case where a semiconductor substrate including a film of a metal is subjected to a CMP treatment and furthermore, is subjected to a cleaning treatment using a cleaning liquid for a semiconductor substrate, the polishing liquid used in the CMP treatment, a residue derived from the semiconductor substrate (for example, an insulating film), and the like remain on the semiconductor substrate.

An object of the present invention is to provide a cleaning liquid for a semiconductor substrate, which is excellent in cleaning performance of organic impurities. In addition, another object of the present invention is to provide a cleaning method for a semiconductor substrate using the cleaning liquid for a semiconductor substrate.

The inventors of the present invention have found that the objects can be accomplished by the following configurations.
[1] A cleaning liquid for a semiconductor substrate, which is used for cleaning a semiconductor substrate, the cleaning liquid comprising:
a compound represented by Formula (A) described later.
[2] The cleaning liquid for a semiconductor substrate according to [1], in which the cleaning liquid contains two or more kinds of the compound represented by Formula (A).
[3] The cleaning liquid for a semiconductor substrate according to [1] or [2], in which R⁵ represents an ethylene group.
[4] The cleaning liquid for a semiconductor substrate according to any one of [1] to [3], in which one of R¹ to R⁴ represents the group represented by *—(R⁵—O)ₙ—H.
[5] The cleaning liquid for a semiconductor substrate according to any one of [1] to [4], in which one of R¹ to R⁴ represents the group represented by *—(R⁵—O)ₙ—H, and remaining three of R¹ to R⁴ represent an alkyl group which may have a substituent.
[6] The cleaning liquid for a semiconductor substrate according to any one of [1] to
[5], in which a content of the compound represented by Formula (A) is 0.1% by mass or more with respect to a total mass of components in the cleaning liquid for a semiconductor substrate excluding a solvent.
[7] The cleaning liquid for a semiconductor substrate according to any one of [1] to
[6], further comprising a quaternary ammonium compound B which does not have the group represented by *—(R⁵—O)ₙ—H.
[8] The cleaning liquid for a semiconductor substrate according to [7], in which a content of the quaternary ammonium compound B is 0.1% by mass or more with respect to a total mass of components in the cleaning liquid for a semiconductor substrate excluding a solvent.
[9] The cleaning liquid for a semiconductor substrate according to any one of [1] to [8], further comprising an anticorrosion agent.
[10] The cleaning liquid for a semiconductor substrate according to [9], in which the anticorrosion agent includes a bicyclic heterocyclic compound.
[11] The cleaning liquid for a semiconductor substrate according to [1] or [9], in which the anticorrosion agent includes a purine compound.
[12] The cleaning liquid for a semiconductor substrate according to any one of [9] to [11], in which the anticorrosion agent includes at least one selected from the group consisting of xanthine, hypoxanthine, and adenine.
[13] The cleaning liquid for a semiconductor substrate according to any one of [1] to [12], further comprising a tertiary amine.
[14] The cleaning liquid for a semiconductor substrate according to [13], in which the tertiary amine includes a tertiary amino alcohol.
[15] The cleaning liquid for a semiconductor substrate according to [13] or [14], in which the tertiary amine includes N-methyldiethanolamine.
[16] The cleaning liquid for a semiconductor substrate according to any one of [1] to [15], further comprising an organic acid.
[17] The cleaning liquid for a semiconductor substrate according to [16], in which the organic acid includes a dicarboxylic acid.
[18] The cleaning liquid for a semiconductor substrate according to any one of [1] to [17], in which a pH is 8.0 to 13.0.
[19] The cleaning liquid for a semiconductor substrate according to any one of [1] to [18], further comprising:
water,
in which a content of the water is 60% by mass or more with respect to a total mass of the cleaning liquid for a semiconductor substrate.
[20] The cleaning liquid for a semiconductor substrate according to any one of [1] to [19], in which the cleaning liquid for a semiconductor substrate is used for cleaning a semiconductor substrate that has been subjected to a chemical mechanical polishing treatment.
[21] A cleaning method for a semiconductor substrate, comprising:
a cleaning step of cleaning a semiconductor substrate that has been subjected to a chemical mechanical polishing treatment, by using the cleaning liquid for a semiconductor substrate according to any one of [1] to [20].

According to the present invention, it is possible to provide a cleaning liquid for a semiconductor substrate, which is excellent in cleaning performance of organic impurities. In addition, according to the present invention, it is possible to provide a cleaning method for a semiconductor substrate using the cleaning liquid for a semiconductor substrate.

### DESCRIPTION OF THE PREFERRED EMBODIMENTS

Hereinafter, an example of a form for carrying out the present invention will be described.

In the present specification, a numerical value range expressed using “to” means a range that includes the preceding and succeeding numerical values of “to” as the lower limit and the upper limit, respectively.

In the present specification, in a case where two or more kinds of a certain component are present, the “content” of the component means the total content of the two or more kinds of the component.

In the present specification, “ppm” means “parts-per-million (10⁻⁶)”, and “ppb” means “parts-per-billion (10⁻⁹)”.

The compounds described in the present specification may include, unless otherwise specified, isomers (compounds having the same number of atoms but having different structures), optical isomers, and isotopes thereof. In addition, only one kind or a plurality of kinds of the isomers and the isotopes may be included.

The bonding direction of the divalent group (for example, —COO—) denoted in the present specification, is not limited unless otherwise specified. For example, in a case where Y is —COO— in a compound represented by a formula of “X—Y—Z”, the above-described compound may be “X—O—CO—Z” or may be “X—CO—O—Z”.

In the present specification, “psi” means pound-force per square inch, where 1 psi=6,894.76 Pa.

In the present specification, the “weight-average molecular weight” means a weight-average molecular weight in terms of polyethylene glycol measured by gel permeation chromatography (GPC).

In the present specification, “the total mass of the components in the cleaning liquid, excluding the solvent” means the total content of all components contained in the cleaning liquid other than the solvent such as water or an organic solvent.

[Cleaning Liquid for Semiconductor Substrate (Cleaning Liquid)]

A cleaning liquid for a semiconductor substrate (hereinafter, also simply referred to as a “cleaning liquid”) according to an embodiment of the present invention is a cleaning liquid that is used for cleaning a semiconductor substrate, where the cleaning liquid contains a compound represented by Formula (A) (hereinafter, also referred to as “compound A”).

Although the mechanism by which the objects of the present invention are achieved through the above-described configuration is not necessarily clearly revealed, the inventors of the present invention presumes as follows.

The compound A is a compound having, in the molecule, a group represented by *—(R⁵—O)ₙ—H described later. It is presumed that in a case of having the compound A, the compound A is likely to be adsorbed to organic impurities, and as a result, the organic impurities can be efficiently removed, whereby, the cleaning performance of the organic impurities is excellent.

Hereinafter, the fact that the cleaning performance of the organic impurities is excellent is also referred to that the effect of the present invention is more excellent.

Hereinafter, each component included in the cleaning liquid will be described.

[Compound A]

The cleaning liquid contains a compound A.

The compound A is a quaternary ammonium compound.

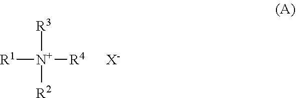

In Formula (A), R¹ to R⁴ each independently represent a substituent. At least one of R¹, . . . , or R⁴ represents a group represented by *—(R⁵—O)ₙ—H. R⁵ represents an alkylene group. n represents an integer of 2 or more. * represents a bonding position. X⁻ represents an anion.

R¹ to R⁴ each independently represent a substituent.

The substituent is preferably a hydrocarbon group which may contain a heteroatom. Examples of the hydrocarbon group include an alkyl group, an alkenyl group, an alkynyl group, an aryl group, and a group obtained by combining these, where an alkyl group is preferable.

Examples of the heteroatom include an oxygen atom, a sulfur atom, and a nitrogen atom.

The hydrocarbon group may further have a substituent.

Examples of the substituent contained in the hydrocarbon group include a halogen atom such as a fluorine atom, a chlorine atom, or a bromine atom; an alkoxy group; a hydroxyl group; an alkoxycarbonyl group such as a methoxycarbonyl group or an ethoxycarbonyl group; an acyl group such as an acetyl group, a propionyl group, or benzoyl group; and a cyano group; a nitro group, where a hydroxyl group is preferable.

In a case where the hydrocarbon group has a substituent, the hydrocarbon group preferably has 1 to 3 substituents and more preferably has one substituent.

The alkyl group, the alkenyl group, and the alkynyl group may be linear, branched, or cyclic. The alkyl group, the alkenyl group, and the alkynyl group preferably have 1 to 20 carbon atoms, more preferably have 1 to 10 carbon atoms, still more preferably have 1 to 5 carbon atoms, and particularly preferably have 1 to 3 carbon atoms.

The alkyl group is preferably an unsubstituted alkyl group or a hydroxyalkyl group, more preferably a methyl group, an ethyl group, a propyl group, a butyl group, or a 2-hydroxyethyl group, and still preferably a methyl group, an ethyl group, or a 2-hydroxyethyl group.

The aryl group may be any one of a monocyclic ring or a polycyclic ring.

The aryl group preferably has 6 to 20 carbon atoms, more preferably has 6 to 10 carbon atoms, and still more preferably has 6 to 8 carbon atoms.

Examples of the aryl group include a benzyl group, a phenyl group, a naphthyl group, an anthryl group, a phenanthryl group, an indenyl group, an acenaphthenyl group, a fluorenyl group, and a pyrenyl group, where a benzyl group or a phenyl group is preferable.

At least one of R¹, . . . , or R⁴ represents a group represented by *—(R⁵—O)ₙ—H. R⁵ represents an alkylene group. n represents an integer of 2 or more. * represents a bonding position.

The alkylene group represented by R⁵ may be linear, branched, or cyclic. The alkylene group preferably has 1 to 10 carbon atoms, more preferably 1 to 5 carbon atoms, and still more preferably 1 to 3 carbon atoms. The alkylene group may further have a substituent. Examples of the substituent include substituents which may be contained in R¹ to R⁴.

The alkylene group is preferably an unsubstituted alkylene group, more preferably a methylene group, an ethylene group, a propylene group, or a butylene group, and still more preferably an ethylene group.

n is preferably an integer of 2 to 5, more preferably 2 or 3, and still more preferably 2.

Specifically, the group represented by “*—(R⁵—O)ₙ—H” preferably includes at least one group selected from the group consisting of a group represented by “*—R⁵—O—R⁵—O—H” and “*—R⁵—O—R⁵—O—R⁵—O—H”, and more preferably includes a group represented by “*—R⁵—O—R⁵—O—H”.

In a case where a plurality of groups represented by *—(R⁵—O)ₙ—H are present, the groups represented by *—(R⁵—O)ₙ—H may be the same or different from each other.

In a case where a plurality of R⁵'s and n's are present, R⁵'s and n's may be respectively the same or different from each other.

Among the above, in Formula (A), all the groups represented by *—(R⁵—O)—H are preferably groups represented by “*—R⁵—O—R⁵—O—H”. In other words, n in all the groups represented by *—(R⁵—O)ₙ—H is preferably 2.

It is preferable that one or two of R¹ to R⁴ represents the group represented by *—(R⁵—O)ₙ—H, it is more preferable that one of R¹ to R⁴ represents the group represented by *—(R⁵—O)ₙ—H, and it is still more preferable that one of R¹ to R⁴ represents the group represented by *—(R⁵—O)—H, and remaining three of R¹ to R⁴ represent an alkyl group which may have a substituent (preferably, an unsubstituted alkyl group or a hydroxyalkyl group).

It is noted that among R¹ to R⁴, groups other than the group represented by *—(R⁵—O)ₙ—H may be bonded to each other to form a ring. The kind of the ring to be formed is not particularly limited, and examples thereof include an aliphatic ring containing a nitrogen atom.

In Formula (A), the total number of hydroxyl groups contained in R¹ to R⁴ is preferably 1 to 4 and more preferably 3 or 4.

X⁻ represents an anion.

Examples of the anion include an acid anion such as a carboxylate ion, a phosphate ion, a sulfate ion, a phosphonate ion, or a nitrate ion, a hydroxide ion, and a halide ion such as a chloride ion, a fluoride ion, or a bromide ion or iodide ion, where a hydroxide ion is preferable.

Examples of the compound A include the following compounds.

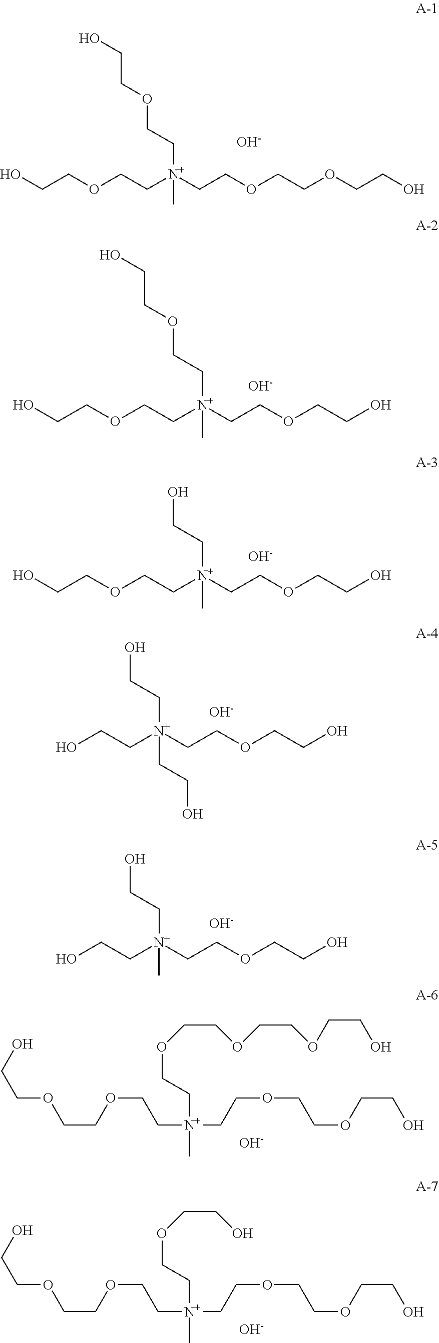

The molecular weight of the compound A is preferably 100 to 500, more preferably 200 to 400, still more preferably 200 to 300, and particularly preferably 200 to 250.

The compound A may be used alone, or two or more kinds thereof may be used in combination.

The number of kinds of the compound A contained in the cleaning liquid is preferably 1 to 10, more preferably 1 to 8, and still more preferably 1 to 4.

With respect to the total mass of the cleaning liquid, the content of the compound A is preferably 0.01% to 10.0% by mass, and it is more preferably 0.1% to 6.0% by mass, and still more preferably 0.5% to 4.9% by mass, from the viewpoint that the effect of the present invention is more excellent.

The content of the compound A is, in many cases, 0.1% by mass or more, preferably 0.1% to 100% by mass, more preferably 1.0% to 80.0% by mass, still more preferably 5.0% to 60.0% by mass, and particularly preferably 10.0% to 55.0% by mass, with respect the total mass of the components in the cleaning liquid, excluding the solvent.

[Quaternary ammonium compound B which does not have group represented by *—(R⁵—O)ₙ—H]

The cleaning liquid preferably contains a quaternary ammonium compound B (hereinafter, also referred to as a “compound B”) which does not have a group represented by *—(R⁵—O)ₙ—H.

The compound B is a quaternary ammonium compound which does not have the group represented by *—(R⁵—O)ₙ—H. Therefore, the compound B is a compound different from the compound A.

The compound B is preferably a compound having a quaternary ammonium cation in which a nitrogen atom is substituted with four hydrocarbon groups (preferably alkyl groups). In addition, the compound B may be a compound having a quaternary ammonium cation in which a nitrogen atom in the pyridine ring is bonded to a substituent (a hydrocarbon group such as an alkyl group or an aryl group), like an alkyl pyridinium.

Examples of the compound B include a quaternary ammonium hydroxide, a quaternary ammonium fluoride, a quaternary ammonium bromide, a quaternary ammonium iodide, a quaternary ammonium acetate, and a quaternary ammonium carbonate.

The compound B is preferably a compound represented by Formula (B).

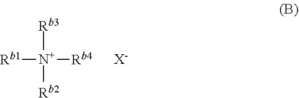

In Formula (B), R^{b1} to R^{b4} each independently represent a hydrocarbon group which may have a substituent. X⁻ represents an anion.

The hydrocarbon group preferably has 1 to 20 carbon atoms, more preferably has 1 to 10 carbon atoms, and still more preferably has 1 to 5 carbon atoms.

Examples of the hydrocarbon group include an alkyl group, an alkenyl group, an alkynyl group, an aryl group, and a group obtained by combining these, where an alkyl group is preferable.

Examples of the substituent contained in the hydrocarbon group include a halogen atom such as a fluorine atom, a chlorine atom, or a bromine atom; an alkoxy group; a hydroxyl group; an alkoxycarbonyl group such as a methoxycarbonyl group or an ethoxycarbonyl group; an acyl group such as an acetyl group, a propionyl group, or benzoyl group; and a cyano group; a nitro group, where a hydroxyl group is preferable.

the hydrocarbon group preferably has 1 to 3 substituents and more preferably has one substituent.

The alkyl group, the alkenyl group, and the alkynyl group may be linear, branched, or cyclic.

The alkyl group is preferably an unsubstituted alkyl group or a hydroxyalkyl group, more preferably a methyl group, an ethyl group, a propyl group, a butyl group, or a 2-hydroxyethyl group, and still preferably a methyl group, an ethyl group, or a 2-hydroxyethyl group.

The aryl group may be any one of a monocyclic ring or a polycyclic ring.

The aryl group preferably has 6 to 20 carbon atoms, more preferably has 6 to 10 carbon atoms, and still more preferably has 6 to 8 carbon atoms.

Examples of the aryl group include a benzyl group, a phenyl group, a naphthyl group, an anthryl group, a phenanthryl group, an indenyl group, an acenaphthenyl group, a fluorenyl group, and a pyrenyl group, where a benzyl group or a phenyl group is preferable.

It is preferable that at least one of R^{b1}, . . . , or R^{b4} represents an alkyl group having a substituent, it is more preferable that at least two of R^{b1} to R^{b4} represent an alkyl group having a substituent, it is still more preferable that at least three of R^{b1} to R^{b4} represent an alkyl group having a substituent, and it is particularly preferable that three of R^{b1} to R^{b4} represent an alkyl group having a substituent, and the remaining one of R^{b1} to R^{b4} represents an unsubstituted alkyl group. It is also preferable that all of R^{b1} to R^{b4} represent an unsubstituted alkyl group.

In addition, as another aspect, it is also preferable that at least two of R^{b1} to R^{b4} represent an alkyl group having a substituent, or all of R^{b1} to R^{b4} represent an unsubstituted alkyl group.

X⁻ represents an anion.

Examples of the anion include an acid anion such as a carboxylate ion, a phosphate ion, a sulfate ion, a phosphonate ion, or a nitrate ion, a hydroxide ion, and a halide ion such as a chloride ion, a fluoride ion, or a bromide ion or iodide ion, where a hydroxide ion is preferable.

Examples of the compound B include tris(2-hydroxyethyl)methylammonium hydroxide (Tris), dimethylbis(2-hydroxyethyl)ammonium hydroxide, tetramethylammonium hydroxide (TMAH), trimethylethylammonium hydroxide (TMEAH), dimethyldiethylammonium hydroxide (DMDEAH), methyltriethylammonium hydroxide (MTEAH), tetraethylammonium hydroxide (TEAH), tetrapropylammonium hydroxide (TPAH), tetrabutylammonium hydroxide (TBAH), 2-hydroxyethyltrimethylammonium hydroxide (choline), ethyltrimethylammonium hydroxide, bis(2-hydroxyethyl)dimethylammonium hydroxide, tri(2-hydroxyethyl)methylammonium hydroxide, tetra(2-hydroxyethyl)ammonium hydroxide, and benzyltrimethylammonium hydroxide (BTMAH).

In addition, examples of the compound B include octenidine dihydrochloride, an alkyltrimethylammonium salt, cetyltrimethylammonium bromide (CTAB), hexadecyltrimethylammonium bromide, cetyltrimethylammonium chloride (CTAC), dimethyldioctadecylammonium chloride, and dioctadecyldimethylammonium bromide (DODAB), where these compounds can also function as a cationic surfactant described later.

The anion in the exemplary compound of the compound B may be an anion other than the above-described anion (for example, the hydroxide). Examples thereof include tris(2-hydroxyethyl)methylammonium bromide.

The molecular weight of the compound B is preferably 90 to 400, more preferably 100 to 200, still more preferably 120 to 200, and particularly preferably 150 to 170 from the viewpoint of further improving the effect of the present invention.

The compound B may be used alone, or two or more kinds thereof may be used in combination.

With respect to the total mass of the cleaning liquid, the content of the compound B is preferably 0.01% to 20.0% by mass, and it is more preferably 0.05% to 9.0% by mass, and still more preferably 1.0% to 5.0% by mass, from the viewpoint that the effect of the present invention is more excellent.

The content of the compound B is, in many cases, 1.0% by mass or more, preferably 1.0% to 98.0% by mass, more preferably 1.0% to 90.0% by mass, still more preferably 20.0% to 70.0% by mass, and particularly preferably 40.0% to 60.0% by mass, with respect the total mass of the components in the cleaning liquid, excluding the solvent.

The mass ratio of the content of the compound A to the content of the compound B (content of compound A/content of compound B) is preferably 0.01 to 20.0, more preferably 0.11 to 1.2, and still more preferably 0.2 to 0.9.

[Tertiary Amine]

The cleaning liquid preferably contains a tertiary amine.

The tertiary amine is a compound having at least a tertiary amino group (>N—) in the molecule. It is a compound different from the anticorrosion agent described later.

Examples of the tertiary amine include a tertiary aliphatic amine and a tertiary amino alcohol, where a tertiary amino alcohol is preferable.

The tertiary amine is preferably a compound represented by Formula (C), and more preferably a compound represented by Formula (C1).

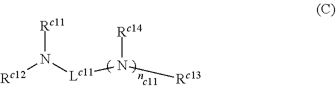

in Formula (C), R^{c11} to R^{c13} each independently represent a hydrocarbon group which may have a substituent, R^{c14} represents a hydrogen atom or a hydrocarbon group which may have a substituent. L^{c11} represents a single bond or a divalent linking group. n^{c11} represents 0 or 1.

R^{c11} to R^{c13} each independently represent a hydrocarbon group which may have a substituent. R^{c14} represents a hydrogen atom or a hydrocarbon group which may have a substituent.

The hydrocarbon group preferably has 1 to 20 carbon atoms, more preferably has 1 to 10 carbon atoms, and still more preferably has 1 to 5 carbon atoms.

Examples of the hydrocarbon group include an alkyl group, an alkenyl group, an alkynyl group, an aryl group, and a group obtained by combining these, where an alkyl group is preferable.

Examples of the substituent contained in the hydrocarbon group include a halogen atom such as a fluorine atom, a chlorine atom, or a bromine atom; an alkoxy group; a hydroxyl group; an alkoxycarbonyl group such as a methoxycarbonyl group or an ethoxycarbonyl group; an acyl group such as an acetyl group, a propionyl group, or benzoyl group; and a cyano group; a nitro group, where a hydroxyl group is preferable.

The alkyl group, the alkenyl group, and the alkynyl group may be linear, branched, or cyclic.

The alkyl group is preferably an unsubstituted alkyl group or a hydroxyalkyl group, more preferably a methyl group, an ethyl group, a propyl group, a butyl group, or a 2-hydroxyethyl group, and still preferably a methyl group, an ethyl group, or a 2-hydroxyethyl group.

The aryl group may be any one of a monocyclic ring or a polycyclic ring.

The aryl group preferably has 6 to 20 carbon atoms, more preferably has 6 to 10 carbon atoms, and still more preferably has 6 to 8 carbon atoms.

Examples of the aryl group include a benzyl group, a phenyl group, a naphthyl group, an anthryl group, a phenanthryl group, an indenyl group, an acenaphthenyl group, a fluorenyl group, and a pyrenyl group, where a benzyl group or a phenyl group is preferable.

At least two of R^{c11} to R^{c14} (for example, R^{c11} and R^{c14}, or R^{c12} and R^{c13}) may be bonded to each other to form a ring. The above-described ring to be formed may be any of a monocyclic ring or a polycyclic ring.

L^{c11} represents a single bond or a divalent linking group.

Examples of the divalent linking group include an ether group, a carbonyl group, an ester group, a thioether group, —SO₂—, -NT- (T represents a substituent), a divalent hydrocarbon group (for example, an alkylene group, an alkenylene group, an alkynylene group, or an arylene group), and a group obtained by combining these.

L^{c11} is preferably a single bond or a divalent hydrocarbon group, and more preferably a single bond or an alkylene group.

n^{c11} represents 0 or 1. n^{c11} is preferably 0.

In a case where n^{c11} is 0, it is preferable that at least one of R^{c11}, . . . , or R^{c13} represents an alkyl group having a hydroxyl group, it is more preferable that at least two of R^{c11} to R^{c13} represent an alkyl group having a hydroxyl group, and it is particularly preferable that two of R^{c11} to R^{c13} represent an alkyl group having a hydroxyl group, and the remaining one of R^{c11} to R^{c13} represents an unsubstituted alkyl group.

In a case where n_{c11} is 1, it is preferable that R^{c11} to R^{c14} represent an unsubstituted alkyl group.

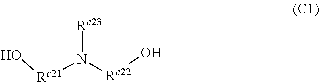

In Formula (C1), R^{c21} and R^{c22} each independently represent an alkylene group which may have an oxygen atom. R^{c23} represents an alkyl group which may have a substituent.

R^{c21} and R^{c22} each independently represent an alkylene group which may have an oxygen atom.

The alkylene group may be linear or branched.

The alkylene group preferably has 1 to 10 carbon atoms, more preferably 1 to 5 carbon atoms, and still more preferably 1 to 3 carbon atoms.

In a case where the alkylene group has an oxygen atom, the number of oxygen atoms is preferably 1 to 5, more preferably 1 to 3, and still more preferably 1 or 2.

Examples of the alkylene group include an alkylene group, an oxyalkylene group, and an alkylene group having a hydroxyl group, where an alkylene group having 1 to 10 carbon atoms or an oxyalkylene group is preferable, an alkylene group having 1 to 10 carbon atoms is more preferable, and an alkylene group having 1 to 3 carbon atoms is still more preferable.

In addition, examples of the alkylene group having an oxygen atom include an oxyalkylene group.

R^{c23} represents an alkyl group which may have a substituent.

The alkyl group may be linear, branched, or cyclic.

Examples of the substituent include substituents which can be contained in R¹ to R⁴ in Formula (A).

R^{c23} is preferably an alkyl group having 1 to 3 carbon atoms, a tert-butyl group, or a phenyl group, and more preferably a methyl group.

<Tertiary Aliphatic Amine>

Examples of the tertiary aliphatic amine include a tertiary amine that has a tertiary amino group in the molecule but does not have an aromatic ring.

Examples of the tertiary aliphatic amine include a tertiary alicyclic amine compound and a tertiary aliphatic amine compound.

(Tertiary Alicyclic Amine Compound)

The tertiary alicyclic amine compound is a tertiary amine having a nitrogen atom as a ring member atom and having a non-aromatic heterocyclic ring.

Examples of the tertiary alicyclic amine compound include a cyclic amidine compound and a piperazine compound.

-Cyclic Amidine Compound-

The cyclic amidine compound is a compound having a heterocyclic ring including an amidine structure (>N—C═N—) in the ring.

The number of ring members of the heterocyclic ring contained in the cyclic amidine compound is not particularly limited; however, it is preferably 5 or 6, and more preferably 6.

Examples of the cyclic amidine compound include diazabicycloundecene (1,8-diazabicyclo[5.4.0]undeca-7-ene: DBU), diazabicyclononene (1,5-diazabicyclo[4.3.0]nona-5-ene: DBN), 3,4,6,7,8,9,10,11-octahydro-2H-pyrimid[1.2-a]azocine, 3,4,6,7,8,9-hexahydro-2H-pyrido[1.2-a]pyrimidine, 2,5,6,7-tetrahydro-3H-pyrrolo[1.2-a]imidazole, 3-ethyl-2,3,4,6,7,8,9,10-octahydropyrimid[1.2-a]azepine, and creatinine. The cyclic amidine compound is preferably DBU or DBN.

-Piperazine Compound-

The piperazine compound is a compound having a hetero-6-membered ring (a piperazine ring) in which the opposite —CH— group of a cyclohexane ring is replaced with a tertiary amino group (>N—).

Examples of the piperazine compound include 1-methylpiperazine, 1-ethylpiperazine, 1-propylpiperazine, 1-butylpiperazine, 1,4-dimethylpiperazine, 1-phenylpiperazine, 1-(2-hydroxyethyl)piperazine (HEP), N-(2-aminoethyl)piperazine (AEP), 1,4-bis(2-hydroxyethyl) piperazine (BHEP), 1,4-bis(2-aminoethyl) piperazine (BAEP), 1,4-bis(3-aminopropyl) piperazine (BAPP), and 1,4-diazabicyclo[2.2.2]octane (DABCO). The piperazine compound is preferably DABCO.

Other examples of the tertiary alicyclic amine compound include a compound having a non-aromatic hetero-5-membered ring such as 1,3-dimethyl-2-imidazolidinone, and an aromatic compound having a 7-membered ring containing a nitrogen atom.

(Tertiary aliphatic amine compound) Examples of the tertiary aliphatic amine compound include a tertiary alkylamine such as trimethylamine or triethylamine, an alkylenediamine such as 1,3-bis(dimethylamino)butane, and a polyalkylpolyamine such as N,N,N′,N″,N″-pentamethyldiethylenetriamine.

<Tertiary Amino Alcohol>

The tertiary amino alcohol is a compound having a tertiary amino group and further having at least one hydroxy group in the molecule. In a case where the cleaning liquid contains a tertiary amino alcohol, the removability of ruthenium oxide is excellent.

Examples of the tertiary amino alcohol include N-methyldiethanolamine (MDEA), 2-(dimethylamino)ethanol (DMAE), N-ethyldiethanolamine (EDEA), 2-diethylaminoethanol, 2-(dibutylamino)ethanol, 2-[2-(dimethylamino)ethoxy]ethanol, 2-[2-(diethylamino)ethoxy]ethanol, triethanolamine, N-butyldiethanolamine (BDEA), N-tert-butyldiethanolamine (t-BDEA), 1-[bis(2-hydroxyethyl)amino]-2-propanol (Bis-HEAP), 2-(N-ethylanilino)ethanol, N-phenyldiethanolamine (Ph-DEA), N-benzyldiethanolamine, p-tolyldiethanolamine, m-tolyldiethanolamine, 2-[[2-(dimethylamino)ethyl]methylamino]ethanol, N,N-bis(2-hydroxyethyl)-3-chloroaniline, and stearyldiethanolamine.

Among them, the tertiary amino alcohol is preferably N-methyldiethanolamine, 2-(dimethylamino)ethanol (DMAE), N-ethyldiethanolamine (EDEA), or 2-diethylaminoethanol, and more preferably N-methyldiethanolamine.

The content of the tertiary amino alcohol is preferably 0.01% to 90.0% by mass, more preferably 0.5% to 65.0% by mass, and still more preferably 1.0% to 25.0% by mass, with respect to the total mass of the cleaning liquid.

The content of the tertiary amino alcohol is preferably 1.0% to 95.0% by mass, more preferably 10.0% to 85.0% by mass, and still more preferably 10.0% to 45.0% by mass with respect to the total mass of the components in the cleaning liquid, excluding the solvent.

One kind of tertiary amine may be used alone, or two or more kinds thereof may be used.

The content of the tertiary amine is preferably 0.01% to 90.0% by mass, more preferably 0.5% to 65.0% by mass, and still more preferably 1.0% to 25.0% by mass, with respect to the total mass of the cleaning liquid.

The content of the tertiary amine is preferably 1.0% to 95.0% by mass, more preferably 10.0% to 85.0% by mass, and still more preferably 10.0% to 45.0% by mass with respect to the total mass of the components in the cleaning liquid, excluding the solvent.

[Other Amine]

The cleaning liquid may contain another amine compound.

Examples of the other amine include a primary amine and a secondary amine, and specific examples thereof include a primary aliphatic amine, a secondary aliphatic amine, a primary amino alcohol, and a secondary amino alcohol.

The primary amine is a compound having a primary amino group in the molecule. The secondary amine is a compound having a secondary amino group in the molecule.

The other amine is a compound different from the anticorrosion agent.

Examples of the primary amino alcohol and the secondary amino alcohol include monoethanolamine (MEA), uracil, 2-amino-2-methyl-1-propanol (AMP), 2-(2-aminoethylamino)ethanol (AAE), 3-amino-1-propanol, 1-amino-2-propanol, N,N′-bis(2-hydroxyethyl)ethylenediamine, trishydroxymethylaminomethane, diethyleneglycolamine (DEGA), 2-(aminoethoxy)ethanol (AEE), N-methylethanolamine, 2-(ethylamino)ethanol, 2-[(hydroxymethyl)amino]ethanol, 2-(propylamino)ethanol, diethanolamine, N-butylethanolamine, and N-cyclohexylethanolamine.

Examples of the primary aliphatic amine and the secondary aliphatic amine include piperazine, 2-methylpiperazine, 2,5-dimethylpiperazine, 2,6-dimethylpiperazine, 2-hydroxypiperazine, and 2-hydroxymethylpiperazine.

Among them, the other amine is preferably a primary amino alcohol or a secondary amino alcohol, and more preferably 2-amino-2-methyl-1-propanol (AMP).

One kind of the other amine may be used alone, or two or more kinds thereof may be used.

The content of the other amine is preferably 0.01% to 90.0% by mass, more preferably 0.5% to 65.0% by mass, and still more preferably 1.0% to 25.0% by mass, with respect to the total mass of the cleaning liquid.

The content of the other amine is preferably 1.0% to 95.0% by mass, more preferably 10.0% to 85.0% by mass, and still more preferably 10.0% to 45.0% by mass with respect to the total mass of the components in the cleaning liquid, excluding the solvent.

[Anticorrosion Agent]

The cleaning liquid preferably contains an anticorrosion agent.

Examples of the anticorrosion agent include a compound having a heteroatom, where a compound having a heterocycle is preferable, and a compound having a heterocycle (for example, a bicycle) is more preferable.

The anticorrosion agent is preferably a purine compound, an azole compound, or a reductive sulfur compound, more preferably a purine compound or an azole compound, and still more preferably a purine compound.

<Purine Compound>

The purine compound is at least one compound selected from the group consisting of purine and a purine derivative. In a case where the cleaning liquid contains a purine compound, it is excellent in anticorrosion properties and hardly remains as a residue.

The purine compound preferably includes at least one selected from the group consisting of compounds represented by any of Formulae (B1) to (B4), more preferably includes at least one selected from the group consisting of a compound represented by Formula (B1) and compounds represented by any of Formulae (B4) to (B7), and still more preferably includes at least one selected from the group consisting of compounds represented by any of Formulae (B5) and (B6).

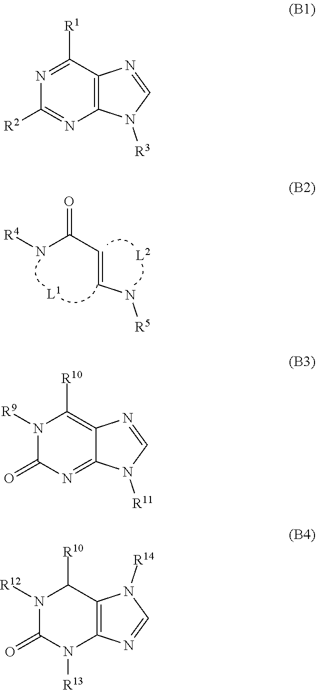

In Formula (B1), R¹ to R³ each independently represent a hydrogen atom, an alkyl group, an amino group, a thiol group, a hydroxyl group, a halogen atom, a sugar group, or a polyoxyalkylene group-containing group.

The alkyl group may be linear, branched, or cyclic.

The alkyl group preferably has 1 to 10 carbon atoms, more preferably has 1 to 5 carbon atoms, and still more preferably has 1 to 3 carbon atoms.

Examples of the sugar group include a group obtained by removing one hydrogen atom from saccharides selected from the group consisting of monosaccharides, disaccharides, and polysaccharides, where a group obtained by removing one hydrogen atom from monosaccharides is preferable.

Examples of the monosaccharides include a pentose such as ribose, deoxyribose, arabinose, or xylose, a triose, a tetrose, a hexose, and a heptose, where a pentose is preferable, ribose, deoxyribose, arabinose, or xylose is more preferable, and ribose or deoxyribose is still more preferable.

Examples of the disaccharides include sucrose, lactose, maltose, trehalose, turanose, and cellobiose.

Examples of the polysaccharides include glycogen, starch, and cellulose.

The saccharides may be chain-like or cyclic, and they are preferably cyclic.

Regarding the cyclic saccharides, examples of the ring include a furanose ring and a pyranose ring.

The polyoxyalkylene group-containing group means a group having a polyoxyalkylene group as a part of the group.

Examples of the polyoxyalkylene group constituting the polyoxyalkylene group-containing group include a polyoxyethylene group, a polyoxypropylene group, and a polyoxybutylene group, where a polyoxyethylene group is preferable.

The alkyl group, the amino group, the sugar group, and the polyoxyalkylene group may further have a substituent.

Examples of the substituent contained in the alkyl group, the amino group, the sugar group, and the polyoxyalkylene group include a hydrocarbon group such as an alkyl group; a halogen atom such as a fluorine atom, a chlorine atom, or a bromine atom; an alkoxy group; a hydroxyl group; an alkoxycarbonyl group such as a methoxycarbonyl group or an ethoxycarbonyl group; an acyl group such as an acetyl group, a propionyl group, or benzoyl group; a cyano group; and a nitro group.

R¹ is preferably a hydrogen atom or an amino group which may have a substituent, and more preferably a hydrogen atom.

Another suitable aspect of R¹ is preferably a hydrogen atom, an alkyl group which may have a substituent, a thiol group, a hydroxyl group, a halogen atom, a sugar group which may have a substituent, or a polyoxyalkylene group-containing group which may have a substituent.

R² is preferably a hydrogen atom or an alkyl group which may have a substituent, and more preferably a hydrogen atom.

R³ is preferably a hydrogen atom, an alkyl group which may have a substituent, or a sugar group which may have a substituent, more preferably a hydrogen atom or an alkyl group which may have a substituent, and still more preferably a hydrogen atom.

In Formula (B2), L¹ represents —CR⁶═N— or —C(═O)—NR⁷—. L² represents —N═CH— or —NR⁸—C(═O)—. R⁴ to R⁸ each independently represent a hydrogen atom, an alkyl group, an amino group, a thiol group, a hydroxyl group, a halogen atom, a sugar group, or a polyoxyalkylene group-containing group.

Examples of R⁴ to R⁸ include groups represented by R¹ to R³ in Formula (B1).

R⁴ and R⁵ are preferably a hydrogen atom or an alkyl group which may have a substituent, and more preferably a hydrogen atom.

R⁶ is preferably a hydrogen atom, an alkyl group which may have a substituent, or an amino group which may have a substituent, more preferably a hydrogen atom or an amino group which may have a substituent, and still more preferably a hydrogen atom.

R⁷ is preferably a hydrogen atom or an alkyl group which may have a substituent, and more preferably a hydrogen atom.

L² is preferably —N═CH—.

R⁸ is preferably a hydrogen atom or an alkyl group which may have a substituent, and more preferably a hydrogen atom.

In Formula (B3), R⁹ to R¹¹ each independently represent a hydrogen atom, an alkyl group, an amino group, a thiol group, a hydroxyl group, a halogen atom, a sugar group, or a polyoxyalkylene group-containing group.

Examples of R⁹ to R¹¹ include groups represented by R¹ to R³ in Formula (B1).

R⁹ is preferably a hydrogen atom or an alkyl group which may have a substituent, and more preferably a hydrogen atom.

R¹⁰ is preferably a hydrogen atom, an alkyl group which may have a substituent, or an amino group which may have a substituent, more preferably a hydrogen atom or an amino group which may have a substituent, and still more preferably an amino group which may have a substituent.

R¹¹ is preferably a hydrogen atom or an alkyl group which may have a substituent, and more preferably a hydrogen atom.

In Formula (B4), R¹² to R¹⁴ each independently represent a hydrogen atom, an alkyl group, an amino group, a thiol group, a hydroxyl group, a halogen atom, a sugar group, or a polyoxyalkylene group-containing group.

Examples of R¹² to R¹⁴ include groups represented by R¹ to R³ in Formula (B1).

R¹² is preferably a hydrogen atom or an alkyl group which may have a substituent, and more preferably an alkyl group which may have a substituent.

Another suitable aspect of R¹² is preferably an alkyl group which may have a substituent, an amino group which may have a substituent, a thiol group, a hydroxyl group, a halogen atom, a sugar group which may have a substituent, or a polyoxyalkylene group-containing group which may have a substituent.

R¹³ is preferably a hydrogen atom or an alkyl group which may have a substituent, and more preferably an alkyl group which may have a substituent.

R¹⁴ is preferably a hydrogen atom or an alkyl group which may have a substituent.

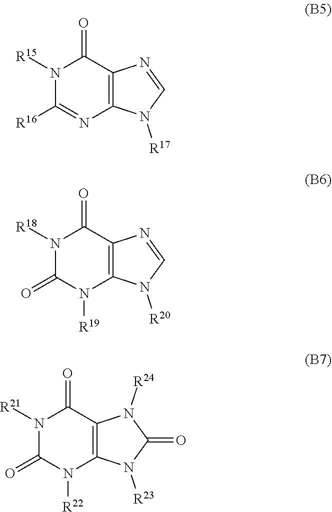

In Formula (B5), R¹⁵ to R¹⁷ each independently represent a hydrogen atom, an alkyl group, an amino group, a thiol group, a hydroxyl group, a halogen atom, a sugar group, or a polyoxyalkylene group-containing group.

Examples of R¹⁵ to R¹⁷ include groups represented by R¹ to R³ in Formula (B1).

R¹⁵ is preferably a hydrogen atom or an alkyl group which may have a substituent, and more preferably a hydrogen atom.

R¹⁶ is preferably a hydrogen atom, an alkyl group which may have a substituent, or an amino group which may have a substituent, more preferably a hydrogen atom or an amino group which may have a substituent, and still more preferably a hydrogen atom.

Another suitable aspect of R¹⁶ is preferably a hydrogen atom, an alkyl group which may have a substituent, a thiol group, a hydroxyl group, a halogen atom, a sugar group which may have a substituent, or a polyoxyalkylene group-containing group which may have a substituent.

R¹¹ is preferably a hydrogen atom or an alkyl group which may have a substituent, and more preferably a hydrogen atom.

In Formula (B6), R¹⁸ to R²⁰ each independently represent a hydrogen atom, an alkyl group, an amino group, a thiol group, a hydroxyl group, a halogen atom, a sugar group, or a polyoxyalkylene group-containing group.

Examples of R¹⁸ to R²⁰ include groups represented by R¹ to R³ in Formula (B1).

R¹⁸ to R²⁰ are preferably a hydrogen atom or an alkyl group which may have a substituent, and more preferably a hydrogen atom.

In Formula (B7), R²¹ to R²⁴ each independently represent a hydrogen atom, an alkyl group, an amino group, a thiol group, a hydroxyl group, a halogen atom, a sugar group, or a polyoxyalkylene group-containing group.

Examples of R²¹ to R²⁴ include groups represented by R¹ to R³ in Formula (B1).

R²¹ to R²⁴ are preferably a hydrogen atom or an alkyl group which may have a substituent, and more preferably a hydrogen atom.

Examples of the purine compound include purine, adenine, guanine, hypoxanthine, xanthine, theobromine, caffeine, uric acid, isoguanine, adenosine, enprofylline, theophylline, xanthosine, 7-methylxanthosine, 7-methylxanthine, theophylline, eritadenine, 3-methyladenine, 3-methylxanthine, 1,7-dimethylxanthine, 1-methylxanthine, 1,3-dipropyl-7-methylxanthine, paraxanthine, 3,7-dihydro-7-methyl-1H-purine-2,6-dione, 1,7-dipropyl-3-methylxanthine, 1-methyl-3,7-dipropylxanthine, 1,3-dipropyl-7-methyl-8-dicyclopropylmethylxanthine, 1,3-dibutyl-7-(2-oxopropyl)xanthine, 1-butyl-3,7-dimethylxanthine, 3,7-dimethyl-1-propylxanthine, mercaptopurine, 2-aminopurine, 6-aminopurine, 6-benzylaminopurine, nelarabine, vidarabine, 2,6-dichloropurine, aciclovir, N⁶-benzoyladenosine, trans-zeatin, 6-benzylaminopurine, entecavir, valaciclovir, abacavir, 2′-deoxyguanosine, disodium inosinate, ganciclovir, guanosine 5′-disodium monophosphate, O-cyclohexylmethylguanine, N²-isobutyryl-2′-deoxyguanosine, β-nicotinamide adenine dinucleotide phosphate, 6-chloro-9-(tetrahydropyran-2-yl)purine, clofarabine, kinetin, 7-(2,3-dihydroxypropyl)theophylline, 6-mercaptopurine, proxyphylline, 2,6-diaminopurine, 2′,3′-dideoxyinosine, theophylline-7-acetic acid, 2-chloroadenine, 2-amino-6-chloropurine, 8-bromo-3-methylxanthine, 2-fluoroadenine, penciclovir, 9-(2-hydroxyethyl)adenine, 7-(2-chloroethyl)theophylline, 2-amino-6-iodopurine, 2-thioxanthine, 2-amino-6-methoxypurine, N-acetylguanine, adefovir dipivoxil, 8-chlorotheophylline, 6-methoxypurine, 1-(3-chloropropyl)theobromine, 6-(dimethylamino)purine, and inosine.

The purine compound preferably includes at least one selected from the group consisting of purine, adenine, guanine, hypoxanthine, xanthine, theobromine, caffeine, uric acid, isoguanine, adenosine, enprofylline, theophylline, xanthosine, 7-methylxanthosine, 7-methylxanthine, theophylline, eritadenine, 3-methyladenine, 3-methylxanthine, 1,7-dimethylxanthine, 1-methylxanthine, and paraxanthine, and it particularly preferably includes at least one selected from the group consisting of xanthine, hypoxanthine, and adenine.

The content of the purine compound is preferably 0.1% to 10.0% by mass, more preferably 1.0% to 8.0% by mass, and still more preferably 4.0% to 8.0% by mass, with respect to the total mass of the cleaning liquid.

The content of the purine compound is preferably 1.0% to 70.0% by mass, more preferably 20.0% to 70.0% by mass, and still more preferably 45.0% to 60.0% by mass with respect to the total mass of the components in the cleaning liquid, excluding the solvent.

The mass ratio of the content of the compound A to the content of the purine compound (content of compound A/content of purine compound) is preferably 0.001 to 50.0, more preferably 0.01 to 2.0, and still more preferably 0.05 to 0.3.

<Azole Compound>

The azole compound is a compound different from the above-described compound that can be contained in the cleaning liquid.

The azole compound is an aromatic compound having a hetero-5-membered ring that contains one or more nitrogen atoms.

The number of nitrogen atoms contained in the hetero-5-membered ring of the azole compound is preferably 1 to 4 and more preferably 1 to 3.

The azole compound may have a substituent on the hetero 5-membered ring.

Examples of the substituent include a hydroxyl group, a carboxy group, a mercapto group, an amino group, an alkyl group having 1 to 4 carbon atoms, which may have an amino group, and a 2-imidazolyl group.

Examples of the azole compound include an imidazole compound in which one of the atoms constituting the azole ring is a nitrogen atom, a pyrazole compound in which two of the atoms constituting an azole ring are nitrogen atoms, and a thiazole compound in which one of the atoms constituting an azole ring is a nitrogen atom and the other is a sulfur atom, a triazole compound in which three of the atoms constituting an azole ring are nitrogen atoms, and a tetrazole compound in which four of the atoms constituting an azole ring are nitrogen atoms.

Examples of the imidazole compound include imidazole, 1-methylimidazole, 2-methylimidazole, 5-methylimidazole, 1,2-dimethylimidazole, 2-mercaptoimidazole, 4,5-dimethyl-2-mercaptoimidazole, 4-hydroxyimidazole, 2,2′-biimidazole, 4-imidazole carboxylic acid, histamine, and benzoimidazole.

Examples of the pyrazole compound include 2,4-dimethylthiazole, benzothiazole, and 2-mercaptobenzothiazole.

Examples of the thiazole compound include 2,4-dimethylthiazole, benzothiazole, and 2-mercaptobenzothiazole.

Examples of the triazole compound include 1,2,4-triazole, 3-methyl-1,2,4-triazole, 3-amino-1,2,4-triazole, 1,2,3-triazole, 1-methyl-1,2,3-triazole, benzotriazole, 1-hydroxybenzotriazole, 1-dihydroxypropylbenzotriazole, 2,3-dicarboxypropylbenzotriazole, 4-hydroxybenzotriazole, 4-carboxybenzotriazole, 5-methylbenzotriazole, and 2,2′-{[(5-methyl-1H-benzotriazole-1-yl)methyl]imino}diethanol. Among them, benzotriazole is preferable.

Examples of the tetrazole compound include 1H-tetrazole (1,2,3,4-tetrazole), 5-methyl-1,2,3,4-tetrazole, 5-amino-1,2,3,4-tetrazole, 1,5-pentamethylenetetrazole, 1-phenyl-5-mercaptotetrazole, and 1-(2-dimethylaminoethyl)-5-mercaptotetrazole.

The azole compound is preferably an imidazole compound or a pyrazole compound, and more preferably pyrazole or 3-amino-5-methylpyrazole.

The content of the azole compound is preferably 0.01% to 10.0% by mass, more preferably 1.0% to 10.0% by mass, and still more preferably 5.0% to 8.0% by mass, with respect to the total mass of the cleaning liquid.

The content of the azole compound is preferably 1.0% to 90.0% by mass, more preferably 10.0% to 80.0% by mass, still more preferably 30.0% to 70.0% by mass, and particularly preferably 45.0% to 60.0% by mass, with respect the total mass of the components in the cleaning liquid, excluding the solvent.

<Reductive Sulfur Compound>

The reductive sulfur compound is a compound that has reducing properties and contains a sulfur atom.

Examples of the reductive sulfur compound include 3-mercapto-1,2,4-triazole, mercaptosuccinic acid, mercaptopropionic acid, dithiodiglycerol, cysteine, cysteamine, thiourea, bis(2,3-dihydroxypropylthio)ethylene, sodium 3-(2,3-dihydroxypropylthio)-2-methyl-propylsulfonate, 1-thioglycerol, sodium 3-mercapto-1-propanesulfonate, 2-mercaptoethanol, thioglycolic acid, and 3-mercapto-1-propanol.

Among them, mercapto compound is preferable, and 1-thioglycerol, sodium 3-mercapto-1-propanesulfonate, 2-mercaptoethanol, 3-mercapto-1-propanol, or thioglycolic acid is more preferable.

The content of the reductive sulfur compound is preferably 0.01% to 10.0% by mass, more preferably 0.05% to 5.0% by mass, and still more preferably 0.1% to 3.0% by mass, with respect to the total mass of the cleaning liquid.

The content of the reductive sulfur compound is preferably 0.01% to 30.0% by mass, more preferably 0.05% to 25.0% by mass, and still more preferably 0.5% to 20.0% by mass with respect to the total mass of the components in the cleaning liquid, excluding the solvent.

[Chelating Agent]

The cleaning liquid may contain a chelating agent.

Examples of the chelating agent include an organic acid and an inorganic acid.

The chelating agent is a compound different from the above-described compound that can be contained in the cleaning liquid. In addition, it is preferable that the compound is different from the surfactant and other components, which are described later.

Examples of the organic acid include a carboxylic acid-based organic acid and a phosphonic acid-based organic acid, where a carboxylic acid-based organic acid is preferable, and a dicarboxylic acid is more preferable.

Examples of the inorganic acid include phosphoric acid.

The chelating agent is preferably citric acid, malic acid, or phosphoric acid.

Examples of the acid group contained in the organic acid include a carboxy group, a phosphonate group, a sulfo group, and a phenolic hydroxyl group.

The organic acid preferably has at least one selected from the group consisting of a carboxy group and a phosphonate group, and more preferably has a carboxy group.

The molecular weight of the organic acid is preferably 600 or less, more preferably 450 or less, and still more preferably 300 or less. The lower limit thereof is preferably 50 or more and more preferably 100 or more.

The organic acid preferably has 1 to 15 carbon atoms and more preferably has 2 to 15 carbon atoms.

The carboxylic acid-based organic acid is an organic acid having at least one carboxy group in the molecule.

Examples of the carboxylic acid-based organic acid include an aliphatic carboxylic acid-based organic acid, an amino polycarboxylic acid-based organic acid, and an amino acid-based organic acid, where an aliphatic carboxylic acid-based organic acid is preferable.

The aliphatic carboxylic acid-based organic acid may further have a hydroxyl group in addition to the carboxylic acid group and the aliphatic group.

Examples of the aliphatic carboxylic acid-based organic acid include oxalic acid, malonic acid, succinic acid, glutaric acid, adipic acid, pimelic acid, sebacic acid, maleic acid, malic acid, citric acid, and tartaric acid, where tartaric acid, citric acid, or malic acid is preferable, and citric acid or malic acid is more preferable from the viewpoint of more excellent anticorrosion properties.

Examples of the amino polycarboxylic acid-based organic acid include the compounds described in paragraphs [0067] and [0068] of WO2018/021038A, the contents of which are incorporated in the present specification.

Examples of the amino acid-based organic acid include the compounds described in paragraphs [0030] to [0033] of JP2020-161511A, the compounds described in paragraphs [0021] to [0023] of JP2016-086094A, and the histidine derivatives described in JP2015-165561A and JP2015-165562A, the contents of which are incorporated in the present specification.

Examples of the phosphonic acid-based organic acid include the compounds described in paragraphs [0026] to [0036] of WO2018/020878A, and paragraphs [0031] to [0046] of WO2018/030006A, the contents of which are incorporated in the present specification.

The organic acid may be used alone, or two or more kinds thereof may be used in combination.

From the viewpoint that the performance of the cleaning liquid is excellent in a well-balanced, the content of the organic acid is preferably 0.01% to 10.0% by mass, more preferably 0.05% to 5.0% by mass, and still more preferably 0.1 to 4.0% by mass with respect to the total mass of the cleaning liquid.

The content of the organic acid is preferably 0.1% to 70.0% by mass, more preferably 0.5% to 50.0% by mass, and still more preferably 1.0% to 40.0% by mass with respect to the total mass of the components in the cleaning liquid excluding the solvent.

[Water]

The cleaning liquid may contain water.

Regarding the kind of water used for the cleaning liquid, distilled water, deionized water, or pure water (ultrapure water) can be used as long as it does not adversely affect a semiconductor substrate. Pure water (ultrapure water) is preferable from the viewpoint that it includes almost no impurities and has less influence on a semiconductor substrate in a step of manufacturing the semiconductor substrate.

It suffices that the content of water is the remainder of the components that can be contained in the cleaning liquid.

The content of water is preferably 1.0% by mass or more, more preferably 30.0% by mass or more, still more preferably 60.0% by mass or more, and particularly preferably 80.0% by mass or more, with respect to the total mass of the cleaning liquid. The upper limit thereof is preferably 99.99% by mass or less, more preferably 99.9% by mass or less, still more preferably 99.0% by mass or less, and particularly preferably 97.0% by mass or less, with respect to the total mass of the cleaning liquid.

[Surfactant]

The cleaning liquid may include a surfactant.

The compound B may function as a surfactant.

The surfactant is a compound having a hydrophilic group and a hydrophobic group (a lipophilic group) in one molecule, and examples thereof include an nonionic surfactant, an anionic surfactant, a cationic surfactant, and an amphoteric surfactant.

In a case where the cleaning liquid contains a surfactant, the corrosion prevention performance of the metal film and the removability of the polishing fine particles are more excellent.

In a large number of cases, the surfactant has at least one hydrophobic group selected from the group consisting of an aliphatic hydrocarbon group, an aromatic hydrocarbon group, and a group obtained by combining these.

In a case where the hydrophobic group includes an aromatic hydrocarbon group, the hydrophobic group contained in the surfactant preferably has 6 or more carbon atoms and more preferably has 10 or more carbon atoms. In a case where the hydrophobic group does not includes an aromatic hydrocarbon group but consists only of an aliphatic hydrocarbon group, the hydrophobic group contained in the surfactant preferably has 9 or more carbon atoms, more preferably has 13 or more carbon atoms, and still more preferably has 16 or more carbon atoms. The upper limit thereof is preferably 20 or less and more preferably 18 or less.

The total number of carbon atoms of the surfactant is preferably 16 to 100.

Examples of the nonionic surfactant include an ester-type nonionic surfactant, an ether-type nonionic surfactant, an ester-ether-type nonionic surfactant, and an alkanolamine-type nonionic surfactant, where an ether-type nonionic surfactant is preferable.

Examples of the nonionic surfactant include polyethylene glycol, alkyl polyglucosides (Triton BG-10 and Triton CG-110 surfactants, manufactured by Dow Chemical Company), octylphenol ethoxylate (Triton X-114, manufactured by Dow Chemical Company), silanepolyalkylene oxide (a copolymer) (Y-17112-SGS preparation, manufactured by Momentive Performance Materials, Inc.), nonylphenol ethoxylates (Tergitol NP-12, manufactured by Dow Chemical Company, and Triton (registered trade name) X-102, X-100, X-45, X-15, BG-10, and CG-119), Silwet (registered trade name) HS-312 (manufactured by Momentive Performance Materials, Inc.), tristyrylphenol ethoxylate (MAKON TSP-20, manufactured by Stepan Company), a polyoxyethylene alkyl ether, a polyoxyethylene alkyl phenyl ether, an alkylallyl formaldehyde-fused polyoxyethylene ether, a polyoxyethylene polyoxypropylene block polymer, a polyoxyethylene polyoxypropylene alkyl ether, a polyoxyethylene ether of glycerin ester, a polyoxyethylene ether of sorbitan ester, a polyoxyethylene ether of sorbitol ester polyethylene glycol fatty acid ester, glycerin ester, polyglycerin ester, sorbitan ester, propylene glycol ester, sucrose ester, an aliphatic acid alkanol amide, a polyoxyethylene fatty acid amide, a polyoxyethylene alkylamide, an alcohol ethoxylate such as BRIJ (registered trade name) 56 (C₁₆H₃₃(OCH₂CH₂)₁₀OH), BRIJ (registered trade name) 58 (C₁₆H₃₃(OCH₂CH₂)₂₀OH), or BRIJ (registered trade name) 35 (C₁₂H₂₅(OCH₂CH₂)₂₃OH), a (primary or secondary) alcohol ethoxylate, an amine ethoxylate, a glucoside, a glucamide, polyethylene glycol, poly(ethylene glycol-co-propylene glycol), cetyl alcohol, stearyl alcohol, cetostearyl alcohol (cetyl and stearyl alcohol), oleyl alcohol, octaethylene glycol monododecyl ether, pentaethylene glycol monododecyl ether, a polyoxypropylene glycol alkyl ether, decylglucoside, laurylglucoside, octylglucoside, polyoxyethylene glycol octylphenol ether, nonoxynol-9, a glycerol alkyl ester, glyceryl laurate, a polyoxyethylene glycol sorbitan alkyl ester, polysorbate, a sorbitan alkyl ester, span, cocamide MEA, cocamide DEA, dodecyldimethylamine oxide, a block copolymer of polypropylene glycol, and mixtures thereof.

Examples of the anionic surfactant include, as a hydrophilic group (an acid group), a phosphoric acid ester-based surfactant having a phosphoric acid ester group, a phosphonic acid-based surfactant having a phosphonate group, a sulfonic acid-based surfactant having a sulfo group, a carboxylic acid-based surfactant having a carboxy group, and a sulfuric acid ester-based surfactant having a sulfuric acid ester group.

Examples of the anionic surfactant include alkylbenzenesulfonic acids such as dodecylbenzenesulfonic acid and ammonium dodecylbenzene sulfonate and salts thereof, alkylnaphthalene sulfonic acids such as propylnaphthalene sulfonic acid and triisopropylnaphthalene sulfonic acid and salts thereof, alkylphenyl ether disulfonic acids such as dodecylphenyl ether disulfonic acid and an alkyldiphenyl ether sulfonic acid and salts thereof; alkyldiphenyl ether disulfonic acids such as dodecyldiphenyl ether disulfonic acid and ammonium dodecyldiphenyl ether sulfonate and salts thereof; phenol sulfonic acid-formalin condensates and salts thereof, arylphenol sulfonic acid-formalin condensates and salts thereof; carboxylates such as decanecarboxylic acid, an N-acylamino acid salt and a polyoxyethylene or polyoxypropylene alkyl ether carboxylate; acylated peptides; sulfonates; sulfate esters such as a sulfated oil, an alkyl sulfate, an alkyl ether sulfate, sulfate ester salts such as a polyoxyethylene or polyoxypropylene alkylallyl ether sulfate and an alkylamide sulfate; phosphate ester salts; alkyl phosphates; polyoxyethylene or polyoxypropylene alkylallyl ether phosphates; ammonium lauryl sulfate; sodium lauryl sulfate (sodium dodecyl sulfate); sodium lauryl ether sulfate (SLES); sodium myreth sulfate; sodium dioctyl sulfosuccinate; octane sulfonate; perfluorooctanesulfonate (PFOS); perfluorobutane sulfonate; alkylbenzene sulfonates; alkylaryl ether phosphates; alkyl ether phosphates; alkyl carboxylates; fatty acid salts (soap); sodium stearate; sodium lauroyl sarcosinate; perfluorononanoate; perfluorooctanoate; and mixtures thereof.

Examples of the cationic surfactant include quaternary ammonium salt-based surfactants and alkyl pyridium-based surfactants.

Examples of the cationic surfactant include cetylpyridinium chloride (CPC), polyethoxylated beef tallow amine (POEA), benzalconium chloride (BAC), benzethonium chloride (BZT), 5-bromo-5-nitro-1,3-dioxane, an aliphatic amine salt; benzalconium chloride salts; benzethonium chloride; and pyridinium salts and imidazolinium salts.

Examples of the amphoteric surfactant include a carboxybetaine-type amphoteric surfactant, a sulfobetaine-type amphoteric surfactant, an aminocarboxylate, imidazolinium betaine, lecithin, an alkylamine oxide, and mixture thereof.

Examples of the surfactant include the compounds described in paragraphs [0092] to [0096] of JP2015-158662A, paragraphs [0045] and [0046] of JP2012-151273A, and paragraphs [0014] to [0020] of JP2009-147389A, the contents of which are incorporated in the present specification.

The surfactant may be used alone, or two or more kinds thereof may be used in combination.

From the viewpoint that the performance of the cleaning liquid is excellent in a well-balanced, the content of the surfactant is preferably 0.001% to 8.0% by mass, more preferably 0.005% to 5.0% by mass, and still more preferably 0.01 to 3.0% by mass, with respect to the total mass of the cleaning liquid.

From the viewpoint that the performance of the cleaning liquid is excellent in a well-balanced manner, the content of the surfactant is preferably 0.01% to 50.0% by mass, more preferably 0.1% to 45.0% by mass, and still more preferably 1.0% to 20.0% by mass, with respect to the total mass of the components in the cleaning liquid, excluding the solvent.

[Other Components]

The cleaning liquid may contain other components.

Examples of other components include a polymer, an oxidizing agent, a polyhydroxy compound having a molecular weight of 500 or more, a pH adjusting agent, a fluorine compound, and an organic solvent.

In addition, examples of the polymer also include the water-soluble polymers described in paragraphs [0043] to [0047] of JP2016-171294A, the contents of which are incorporated in the present specification.

Examples of the oxidizing agent include a peroxide, a persulfide (for example, a monopersulfide or a dipersulfide), a percarbonate, or an acid thereof or a salt thereof.

Examples of the oxidizing agent include an oxidative halide (a periodic acid such as iodic acid, metaperiodic acid, or orthoperiodic acid, or a salt thereof), a perboric acid, a perboric acid salt, a cerium compound, and a ferricyanide (potassium ferricyanide or the like).

The content of the oxidizing agent is preferably 0.01% to 10.0% by mass, more preferably 0.05% to 5.0% by mass, and still more preferably 0.1% to 3.0% by mass, with respect to the total mass of the cleaning liquid.

The content of the oxidizing agent is preferably 0.1% to 50.0% by mass, more preferably 1.0% to 30.0% by mass, and still more preferably 3.0% to 10.0% by mass with respect to the total mass of the components in the cleaning liquid, excluding the solvent.

The polyhydroxy compound having a molecular weight of 500 or more is a compound different from the above-described compound that can be contained in the cleaning liquid.

The polyhydroxy compound is an organic compound having two or more (for example, 2 to 200) alcoholic hydroxyl groups in one molecule.

The molecular weight (the weight-average molecular weight in a case of having a molecular weight distribution) of the polyhydroxy compound is 500 or more, and it is preferably 500 to 100,000 and more preferably 500 to 3,000.

Examples of the polyhydroxy compound include polyoxyalkylene glycols such as polyethylene glycol, polypropylene glycol, and polyoxyethylene polyoxypropylene glycol; oligosaccharides such as manninotriose, cellotriose, gentianose, raffinose, melezitose, cellotetrose, and stachyose; and polysaccharides such as starch, glycogen, cellulose, chitin, and chitosan, and hydrolysates thereof.

It is also preferable that the polyhydroxy compound is cyclodextrin.

The cyclodextrin means one kind of cyclic oligosaccharide having a cyclic structure in which a plurality of D-glucoses are bonded by a glucoside bond. A compound in which 5 or more (for example, 6 to 8) glucoses are bonded is known.

Examples of the cyclodextrin include α-cyclodextrin, β-cyclodextrin, and γ-cyclodextrin, where γ-cyclodextrin is preferable.

The polyhydroxy compound may be used alone, or two or more kinds thereof may be used in combination.

The content of the polyhydroxy compound is preferably 0.01% to 10.0% by mass, more preferably 0.05% to 5.0% by mass, and still more preferably 0.1% to 3.0% by mass, with respect to the total mass of the cleaning liquid.

The content of the polyhydroxy compound is preferably 0.01% to 30.0% by mass, more preferably 0.05% to 25.0% by mass, and still more preferably 0.5% to 20.0% by mass with respect to the total mass of the components of the cleaning liquid, excluding the solvent.

Examples of the pH adjusting agent include a basic compound and an acidic compound, which are different from the above-described compounds that can be contained in the cleaning liquid. However, it is permissible to adjust the pH of the cleaning liquid by adjusting the adding amount of each of the above-described components.

The pH adjusting agent is preferably sulfuric acid or potassium hydroxide.

Examples of the pH adjusting agent include those described in paragraphs [0053] and [0054] of WO2019-151141A and paragraphs [0021] of WO2019-151001A, the contents of which are incorporated in the present specification.

Examples of the fluorine compound include the compounds described in paragraphs [0013] of JP2005-150236A, the contents of which are incorporated in the present specification.

As the organic solvent, a known organic solvents can be used, where a hydrophilic organic solvent such as an alcohol or a ketone is preferable. The organic solvent may be used alone, or two or more kinds thereof may be used in combination.

The using amounts of the fluorine compound and the organic solvent may be appropriately set within a range where the effect of the present invention is not impaired.

Examples of the organic solvent include known organic solvents.

The content of each of the above-described components in the cleaning liquid can be measured according to a known method such as gas chromatography-mass spectrometry (GC-MS), liquid chromatography-mass spectrometry (LC-MS), or ion-exchange chromatography (IC).

[Physical Properties of Cleaning Liquid]

<pH>

The cleaning liquid may be neutral, alkaline, or acidic.

From the viewpoint that the performance of the cleaning liquid is excellent in a well-balanced manner, the pH of the undiluted cleaning liquid is preferably 6.0 to 14.0, more preferably 8.0 to 13.0, and still more preferably 10.0 to 13.0.

In a case where the cleaning liquid is diluted to be used, the pH of the diluted cleaning liquid (for example, 100-fold dilution (in terms of mass ratio or volume ratio)) is preferably 6.0 to 14.0, more preferably 8.0 to 13.0, and still more preferably 10.0 to 13.0.

The pH of the cleaning liquid can be measured by a method based on JIS Z8802-1984, using a known pH meter. The measurement temperature of the pH is 25° C.

<Metal Content>

In the cleaning liquid, the content (measured as the ion concentration) of metals (metal elements of Fe, Co, Na, Cu, Mg, Mn, Li, Al, Cr, Ni, Zn, Sn, and Ag) contained as impurities in the liquid is preferably 5 ppm by mass or less and more preferably 1 ppm by mass or less. In a view that high-purity cleaning liquids are further demanded in the manufacture of state-of-the-art semiconductor elements, the content of the metal is still more preferably a value of less than 1 ppm by mass, that is, a mass of ppb order or less, and particularly preferably 100 ppb by mass or less, and most preferably less than 10 ppb by mass. The lower limit thereof is preferably 0.

Examples of a method for reducing the metal content include carrying out a purification treatment such as distillation and filtration using an ion exchange resin or a filter at a stage of raw materials used in the production of the cleaning liquid or a stage after the production of the cleaning liquid.

Other examples of the method for reducing the metal content include using a container with less elution of impurities, which will be described later as a container that accommodates the raw material or the produced cleaning liquid. In addition, other examples of the method include lining an inner wall of a pipe with a fluororesin so that the metal component does not elute from the pipe and the like during the production of the cleaning liquid.

<Coarse Particle>

The cleaning liquid may include coarse particles, but the content of the cleaning liquid is preferably low.

The coarse particles mean particles having a diameter (particle diameter) of 0.03 m or more in a case where the shape of the particles is regarded as a sphere.

As for the content of the coarse particles in the cleaning liquid, the content of the particles having a particle diameter of 0.1 m or more is preferably 10,000 or less, and more preferably 5,000 or less per 1 mL of the cleaning liquid. The lower limit thereof is preferably 0 or more and more preferably 0.01 or more per 1 mL of the cleaning liquid.

The coarse particles contained in the cleaning liquid correspond to particles of dirt, dust, organic solids, inorganic solids, and the like contained as impurities in raw materials, and particles of dirt, dust, organic solids, and inorganic solids brought in as contaminants during the preparation of the cleaning liquid, in which the particles are finally present as particles without being dissolved in the cleaning liquid.

The content of the coarse particles present in the cleaning liquid can be measured in a liquid phase by using a commercially available measuring device in a light scattering type liquid particle measuring method using a laser as a light source.

Examples of a method for removing the coarse particles include a purification treatment such as filtering which will be described later.

[Production of Cleaning Liquid]

The cleaning liquid can be produced by a known method. Hereinafter, a method for producing the cleaning liquid will be described in detail.

<Liquid Preparation Step>

Regarding a liquid preparation method for a cleaning liquid, it is possible to produce a cleaning liquid, for example, by mixing the above-described respective components.

Regarding the order and/or the timing of mixing the above-described respective components, the preparation method includes, for example, a method in which the compound A and, as necessary, any component such as the compound B are added sequentially to a container to which purified pure water has been added, and then mixed with stirring while a pH adjusting agent is added to the mixture to adjust the pH of the mixed solution, thereby carrying out the preparation. In addition, in a case where water and the respective components are added to the container, they may be added all at once or dividedly a plurality of times.

As a stirring device and a stirring method, which are used in the preparation of the cleaning liquid, a known device may be used as a stirrer or a disperser. Examples of the stirrer include an industrial mixer, a portable stirrer, a mechanical stirrer, and a magnetic stirrer. Examples of the disperser include an industrial disperser, a homogenizer, an ultrasonic disperser, and a bead mill.

The mixing of the respective components in the liquid preparation step for the cleaning liquid, and a purification treatment which will be described later, and the storage of the produced cleaning liquid are preferably carried out at a temperature of 40° C. or lower and more preferably at 30° C. or lower. In addition, the lower limit thereof is preferably 5° C. or higher, and more preferably 10° C. or higher. In a case of preparing, treating, and/or storing the cleaning liquid in the temperature range, it is possible to maintain stable performance for a long period of time.

(Purification Treatment)

It is preferable to subject any one or more of the raw materials for preparing the cleaning liquid to a purification treatment in advance. Examples of the purification treatment include known methods such as distillation, ion exchange, and filtration (filtering).

Regarding the degree of purification, it is preferable to carry out the purification until the purity of the raw material is 99% by mass or more, and it is more preferable to carry out the purification until the purity of the stock solution is 99.9% by mass or more. The upper limit thereof is preferably 99.9999% by mass or less.

Examples of the method for the purification treatment include a method of passing a raw material through an ion exchange resin, a reverse osmosis membrane (a RO membrane), or the like, distillation of a raw material, and filtering described later.

As the purification treatment, a plurality of the above-described purification methods may be combined and carried out. For example, the raw materials are subjected to primary purification by passing through an RO membrane, and then subjected to secondary purification by passing through a purification device consisting of a cation exchange resin, an anion exchange resin, or a mixed bed type ion exchange resin.

In addition, the purification treatment may be carried out a plurality of times.

(Filtering)

Examples of the filter to be used for the filtering include a known filter for filtering. Examples thereof include a filter consisting of a fluororesin such as polytetrafluoroethylene (PTFE) and a tetrafluoroethylene-perfluoroalkyl vinyl ether copolymer (PFA), a polyamide-based resin such as nylon, and a polyolefin resin (including a high-density polyolefin and an ultrahigh-molecular-weight polyolefin) such as polyethylene and polypropylene (PP). Among these materials, a material selected from the group consisting of the polyethylene, the polypropylene (including a high-density polypropylene), the fluororesin (including PTFE and PFA), and the polyamide-based resin (including nylon) is preferable, and among these, the filter with the fluororesin is more preferable. In a case of carrying out filtering of the raw materials using a filter formed with these materials, it is possible to effectively remove high-polarity foreign matters which are likely to cause defects.

The critical surface tension of the filter is preferably 70 to 95 mN/m and more preferably 75 to 85 mN/m. It is noted that the value of the critical surface tension of the filter is a nominal value of a manufacturer. In a case of using a filter having a critical surface tension in the range, it is possible to effectively remove high-polarity foreign matters which are likely to cause defects.

The pore diameter of the filter is preferably 2 to 20 nm and more preferably 2 to 15 nm. By adjusting the pore diameter of the filter to be in the range, it is possible to reliably remove fine foreign matters such as impurities and aggregates included in the raw materials while suppressing clogging in filtering. With regard to the pore diameters herein, reference can be made to nominal values of filter manufacturers.

Filtering may be carried out only once or twice or more. In a case where filtering is carried out twice or more, the filters used may be the same as or different from each other.

Moreover, the filtering is preferably carried out at room temperature (25° C.) or lower, more preferably carried out at 23° C. or lower, and still more preferably carried out at 20° C. or lower. In addition, the temperature is preferably 0° C. or higher, more preferably 5° C. or higher, and still more preferably 10° C. or higher. In a case of carrying out filtering in the temperature range, it is possible to reduce the amounts of particulate foreign matter and impurities dissolved in the raw material and efficiently remove the foreign matter and impurities.

(Container)

The cleaning liquid (including an aspect of a diluted cleaning liquid described later) can be filled in any container and stored, transported, and used as long as corrosiveness does not become a problem.

In the use application for a semiconductor, the container is preferably a container which has a high degree of cleanliness inside the container and in which the elution of impurities from an inner wall of an accommodating portion of the container into each liquid is suppressed. Examples of such a container include various containers commercially available as a container for a semiconductor cleaning liquid, such as “CLEAN BOTTLE” series manufactured by AICELLO MILIM CHEMICAL Co., Ltd., and “PURE BOTTLE” manufactured by Kodama Plastics Co., Ltd., but the container is not limited thereto.

In addition, as the container for accommodating the cleaning liquid, a container in which a liquid contact portion with each liquid, such as an inner wall of the accommodating portion, is formed from a fluororesin (perfluororesin) or a metal which has been subjected to rust prevention and metal elution prevention treatments is preferable.

The inner wall of the container is preferably formed from one or more resins selected from the group consisting of a polyethylene resin, a polypropylene resin, and a polyethylene-polypropylene resin, another resin different from these resins, and a metal which has been subjected to rust prevention and metal elution prevention treatments, such as stainless steel, Hastelloy, Inconel, and Monel.

The other resin described above is preferably a fluororesin (perfluororesin). In this manner, by using a container having an inner wall formed of a fluororesin, the occurrence of a problem of elution of ethylene or propylene oligomers can be suppressed, as compared with a container having an inner wall formed of a polyethylene resin, a polypropylene resin, or a polyethylene-polypropylene resin.

Examples of such a container having an inner wall which is a fluororesin include a FluoroPure PFA composite drum manufactured by Entegris Inc. In addition, the containers described on page 4 of JP1991-502677A (JP-H3-502677A), page 3 of WO2004/016526A, and pages 9 and 16 of WO99/46309A can also be used.

Further, for the inner wall of the container, quartz and an electropolished metal material (that is, a completely electropolished metal material) are also preferably used, in addition to the above-described fluororesin.

The metal material that is used for producing the electropolished metal material is preferably a metal material which includes at least one selected from the group consisting of chromium and nickel, and has a total content of chromium and nickel of more than 25% by mass with respect to the total mass of the metal material, and examples thereof include stainless steel and a nickel-chromium alloy.

The total content of chromium and nickel in the metal material is more preferably 30% by mass or more with respect to the total mass of the metal material. The upper limit thereof is preferably 90% by mass or less.

As a method for electropolishing the metal material, the known method can be used. For example, the methods described in paragraphs [0011] to [0014] of JP2015-227501A, paragraphs [0036] to [0042] of JP2008-264929A, or the like can be used.

The inside of these containers is preferably cleaned before the cleaning liquid is filled. For the liquid used for the cleaning, the amount of the metal impurities in the liquid is preferably reduced. The cleaning liquid may be bottled in a container such as a gallon bottle and a coated bottle after the production, and then may be transported and stored.

In order to prevent the change in the components in the cleaning liquid during the storage, the inside of the container may be replaced with inert gas (nitrogen, argon, or the like) with a purity of 99.99995% by volume or more. In particular, a gas having a low moisture content is preferable. In addition, during the transportation and the storage, the temperature may be normal temperature or may be controlled in a range of −20° C. to 20° C. to prevent deterioration.

(Clean Room)

It is preferable that the handling including the production of the cleaning liquid, the opening and cleaning of a container, the filling of the cleaning liquid, and the like, the treatment analysis, and the measurement are all carried out in a clean room. It is preferable that the clean room satisfies 14644-1 clean room standards. It is preferable that the clean room satisfies any one of International Organization for Standardization (ISO) Class 1, ISO Class 2, ISO Class 3, or ISO Class 4, it is more preferable that the clean room satisfies ISO Class 1 or ISO Class 2, and it is still more preferable that the clean room satisfies ISO Class 1.

<Diluting Step>

After undergoing a diluting step of carrying out dilution with a diluent such as water, the cleaning liquid may be used for cleaning a semiconductor substrate as a cleaning liquid (a diluted cleaning liquid) which has been diluted.

It is noted that the diluted cleaning liquid is also a form of the cleaning liquid according to the embodiment of the present invention as long as the requirements of the present invention are satisfied.

The dilution ratio of the cleaning liquid in the diluting step may be appropriately adjusted according to the kind and the content of each component, the semiconductor substrate as an object to be cleaned. However, the ratio (the dilution ratio) of the diluted cleaning liquid to the cleaning liquid before dilution is preferably 10 to 10,000, more preferably 20 to 3,000, and still more preferably 50 to 1,000 in terms of mass ratio or volume ratio (volume ratio at 23° C.).

In addition, the cleaning liquid is preferably diluted with water from the viewpoint that it has more excellent defect inhibition performance.

That is, it is also possible suitably put into practical use a cleaning liquid (a diluted cleaning liquid) containing each component with an amount obtained by dividing a suitable content of each component (excluding water) contained in the above-described cleaning liquid by a dilution ratio (for example, 100) in the above-described range.

In other words, the suitable content of each component (excluding water) with respect to the total mass of the diluted cleaning liquid is an amount obtained, for example, by dividing the amount described as a suitable content of each component with respect to the total mass of the cleaning liquid (the cleaning liquid before dilution) by a dilution ratio (for example, 100) in the above-described range.

The change in the pH before and after dilution (the difference between the pH of the cleaning liquid before dilution and the pH of the diluted cleaning liquid) is preferably 2.5 or less, more preferably 1.8 or less, and still more preferably 1.5 or less. The lower limit thereof is preferably 0.1 or more.

It is preferable that the pH of the cleaning liquid before the dilution and the pH of the diluted cleaning liquid are each the suitable aspects described above.

A specific method for the diluting step of diluting the cleaning liquid may be carried out according to the above-described liquid preparation step for the cleaning liquid. Regarding the stirring device and the stirring method as well, which are used in the diluting step, the known stirring device mentioned in the liquid preparation step for the cleaning liquid may be used.

It is preferable to subject the water that is used in the diluting step to a purification treatment in advance. In addition, it is preferable to subject a diluted cleaning liquid obtained in a diluting step to a purification treatment.

Examples of the purification treatment include the ion component reducing treatment using an ion exchange resin, an RO membrane, or the like, and the foreign matter removal using filtering, which are described as the purification treatment for the cleaning liquid described above, and it is preferable to carry out any one of these treatments.

[Use Application of Cleaning Liquid]

The cleaning liquid is preferably used in a cleaning step of cleaning a semiconductor substrate, and more preferably used in a cleaning step of cleaning a semiconductor substrate that has been subjected to a CMP treatment. In addition, the cleaning liquid can also be used for cleaning a semiconductor substrate in a process of manufacturing a semiconductor substrate.

As described above, for the cleaning of the semiconductor substrate, a diluted cleaning liquid obtained by diluting the cleaning liquid may be used.

[Object to be Cleaned]

Examples of the object to be cleaned by the cleaning liquid include a semiconductor substrate having a metal-containing substance.

It is noted that in a case where “on the semiconductor substrate” is described, it encompasses, for example, front and back surfaces, a side surface, and the inside of a groove of the semiconductor substrate. In addition, the metal-containing substance on the semiconductor substrate encompasses not only a case where the metal-containing substance is directly on the surface of the semiconductor substrate but also a case where the metal-containing substance is present on the semiconductor substrate through another layer.

Examples of the semiconductor substrate having a Cu-containing substance include a semiconductor substrate that has a Cu-containing metal wire and/or a Cu-containing plug material.

Examples of the metal contained in the metal-containing substance include at least one metal M selected from the group consisting of copper (Cu), aluminum (Al), ruthenium (Ru), cobalt (Co), tungsten (W), titanium (Ti), tantalum (Ta), chromium (Cr), hafnium (Hf), osmium (Os), platinum (Pt), nickel (Ni), manganese (Mn), zirconium (Zr), molybdenum (Mo), lanthanum (La), and iridium (Ir).

The metal-containing substance may be any substance containing a metal (a metal atom), and examples thereof include a single body of the metal M, an alloy including the metal M, an oxide of the metal M, a nitride of the metal M, and an oxynitride of the metal M.

The metal-containing substance may be a mixture containing two or more of these compounds.

It is noted that the oxide, the nitride, and the oxynitride may be respectively any of a composite oxide, a composite nitride, and a composite oxynitride, which contain a metal.

The content of the metal atom in the metal-containing substance is preferably 10% by mass or more, more preferably 30% by mass or more, and still more preferably 50% by mass or more with respect to the total mass of the metal-containing substance. The upper limit thereof is preferably 100% by mass or less.

The semiconductor substrate preferably has a metal M-containing substance containing the metal M, more preferably has a metal-containing substance containing at least one metal selected from the group consisting of Cu, Al, W, Co, Ti, Ta, Ru, and Mo, still more preferably has a metal-containing substance containing at least one metal selected from the group consisting of W, Co, Cu, Al, Ti, Ta, and Ru (a tungsten-containing substance, a cobalt-containing substance, a copper-containing substance, a titanium-containing substance, a tantalum-containing substance, and a ruthenium-containing substance), and particularly preferably has a metal-containing substance containing the Cu metal.

Examples of the semiconductor substrate, which is an object to be cleaned by using the cleaning liquid, include a substrate having a metal wiring line film, a barrier metal, and an insulating film on a surface of a wafer constituting the semiconductor substrate.

Examples of the wafer constituting a semiconductor substrate include a wafer consisting of a silicon-based material, such as a silicon (Si) wafer, a silicon carbide (SiC) wafer, and a silicon-including resin-based wafer (glass epoxy wafer), a gallium phosphorus (GaP) wafer, a gallium arsenic (GaAs) wafer, and an indium phosphorus (InP) wafer.

Examples of the silicon wafer include an n-type silicon wafer in which a silicon wafer is doped with a pentavalent atom (for example, phosphorus (P), arsenic (As), and antimony (Sb)) and a p-type silicon wafer in which a silicon wafer is doped with a trivalent atom (for example, boron (B) and gallium (Ga)). Examples of the silicon of the silicon wafer include amorphous silicon, single crystal silicon, polycrystalline silicon, and polysilicon.

Among them, it is preferably a wafer consisting of a silicon-based material, such as a silicon wafer, a silicon carbide wafer, or a resin-based wafer (a glass epoxy wafer) including silicon.

The semiconductor substrate may have an insulating film on the wafer.

Examples of the insulating film include a silicon oxide film (for example, a silicon dioxide (SiO₂) film, a tetraethyl orthosilicate (Si(OC₂H₅)₄) film (a TEOS film), a silicon nitride film (for example, silicon nitride (Si₃N₄), and silicon nitride carbide (SiNC)), and a low-dielectric-constant (Low-k) film (for example, a carbon-doped silicon oxide (SiOC) film and a silicon carbide (SiC) film), where a low-dielectric-constant (Low-k) film is preferable.

The metal-containing substance is also preferably a metal film containing a metal.

The metal film included in the semiconductor substrate is preferably a metal film containing the metal M, more preferably a metal film containing at least one metal selected from the group consisting of Cu, Al, W, Co, Ti, Ta, Ru, and Mo, still more preferably a metal film containing at least one metal selected from the group consisting of W, Co, Cu, Al, Ti, Ta, and Ru, particularly preferably a metal film containing at least one metal selected from the group consisting of W, Co, Cu, and Ru, and most preferably a metal film containing the Cu metal.

Examples of the metal film containing at least one metal selected from the group consisting of W, Co, Cu, and Ru include a film containing tungsten as a main component (a W-containing film), a film containing cobalt as a main component (a Co-containing film), a film containing copper as a main component (a Cu-containing film), and a film containing ruthenium as a main component (a Ru-containing film).

It is also preferable that the semiconductor substrate has a copper-containing film (a metal film containing copper as a main component).

Examples of the copper-containing film include a wiring line film consisting of only metal copper (copper wiring line film), and a wiring line film made of an alloy consisting of metal copper and another metal (a copper alloy wiring line film).

Examples of the copper alloy wiring line film include a wiring line film made of an alloy consisting of one or more metals selected from aluminum (Al), titanium (Ti), chromium (Cr), manganese (Mn), tantalum (Ta), and tungsten (W), and copper. More specific examples of the copper alloy wiring line film include a copper-aluminum alloy wiring line film (a CuAl alloy wiring line film), a copper-titanium alloy wiring line film (a CuTi alloy wiring line film), a copper-chromium alloy wiring line film (a CuCr alloy wiring line film), a copper-manganese alloy wiring line film (a CuMn alloy wiring line film), a copper-tantalum alloy wiring line film (a CuTa alloy wiring line film), and a copper-tungsten alloy wiring line film (a CuW alloy wiring line film).

Examples of the ruthenium-containing film include a metal film consisting of only metallic ruthenium (a ruthenium metal film) and a metal film made of an alloy consisting of metallic ruthenium and another metal (a ruthenium alloy metal film). The ruthenium-containing film is often used as a barrier metal.

Examples of the tungsten-containing film (the metal film containing tungsten as a main component) include a metal film consisting of only tungsten (a tungsten metal film) and a metal film made of an alloy consisting of tungsten and another metal (a tungsten alloy metal film).

Examples of the tungsten alloy metal film include a tungsten-titanium alloy metal film (a WTi alloy metal film), and a tungsten-cobalt alloy metal film (a WCo alloy metal film).

The tungsten-containing film is used, for example, as a barrier metal or a connection part between the via and the wiring line.

Examples of the cobalt-containing film (metal film containing cobalt as a main component) include a metal film consisting of only metal cobalt (cobalt metal film), and a metal film (cobalt alloy metal film) made of an alloy consisting of metal cobalt and another metal.

Examples of the cobalt alloy metal film include a metal film made of an alloy consisting of one or more metals selected from titanium (Ti), chromium (Cr), iron (Fe), nickel (Ni), molybdenum (Mo), palladium (Pd), tantalum (Ta), and tungsten (W), and cobalt. More specific examples of the cobalt alloy metal film include a cobalt-titanium alloy metal film (a CoTi alloy metal film), a cobalt-chromium alloy metal film (a CoCr alloy metal film), a cobalt-iron alloy metal film (a CoFe alloy metal film), a cobalt-nickel alloy metal film (a CoNi alloy metal film), a cobalt-molybdenum alloy metal film (a CoMo alloy metal film), a cobalt-palladium alloy metal film (a CoPd alloy metal film), a cobalt-tantalum alloy metal film (a CoTa alloy metal film), and a cobalt-tungsten alloy metal film (a CoW alloy metal film).

Further, the cleaning liquid may be preferably used for cleaning a substrate which has, on a wafer constituting a semiconductor substrate, at least a copper-containing wiring line film and a metal film (a cobalt barrier metal) that is composed of only metallic cobalt and is a barrier metal of the copper-containing wiring line film, where the copper-containing wiring line film is in contact with the cobalt barrier metal on the surface of the substrate.

Methods for forming the insulating film, the ruthenium-containing film, the tungsten-containing film, the copper-containing film, and the cobalt-containing film on a wafer constituting the semiconductor substrate are not particularly limited as long as they are methods that are generally carried out in this field.

Examples of a method of forming an insulating film include a method in which a wafer constituting a semiconductor substrate is subjected to a heat treatment in the presence of oxygen gas to form a silicon oxide film, and then a gas of silane and ammonia is introduced thereto to form a silicon nitride film by a chemical vapor deposition (CVD) method.

Examples of the method of forming a ruthenium-containing film, a tungsten-containing film, a copper-containing film, and a cobalt-containing film include a method of forming a circuit on a wafer having the above-described insulating film by a known method using a means such as a resist, and then forming a ruthenium-containing film, a tungsten-containing film, a copper-containing film, and a cobalt-containing film according to a method such as plating or a CVD method.

<Cmp Treatment>

The CMP treatment is a treatment in which a surface of a substrate having a metal wiring line film, a barrier metal, and an insulating film is flattened by a combined action of a chemical action using a polishing slurry including polishing fine particles (abrasive grains) and mechanical polishing.

A surface of the semiconductor substrate that has been subjected to the CMP treatment may have impurities remaining thereon, such as abrasive grains (for example, silica and alumina) used in the CMP treatment, a polished metal wiring line film, and metal impurities (metal residue) derived from the barrier metal. In addition, organic impurities derived from a CMP treatment liquid used in the CMP treatment may remain. For example, since these impurities may short-circuit the wiring lines and deteriorate the electrical characteristics of the semiconductor substrate, the semiconductor substrate that has been subjected to the CMP treatment is subjected to a cleaning treatment for removing these impurities from the surface.

Examples of the semiconductor substrate that has been subjected to the CMP treatment include the substrate that has been subjected to a CMP treatment, described in Vol. 84, No. 3, 2018; however, examples thereof are not limited thereto.

<Buffing Treatment>

A surface of the semiconductor substrate, which is an object to be cleaned by using the cleaning liquid, may be subjected to a CMP treatment and then to a buffing treatment.

The buffing treatment is a treatment of reducing impurities on the surface of the semiconductor substrate using a polishing pad. Specifically, the surface of the semiconductor substrate that has been subjected to the CMP treatment is brought into contact with the polishing pad, and the semiconductor substrate and the polishing pad are relatively slid while supplying a composition for a buffing treatment to the contact portion. As a result, impurities on the surface of the semiconductor substrate are removed by a frictional force of the polishing pad and a chemical action of a composition for a buffing treatment.

As the composition for a buffing treatment, a known composition for a buffing treatment can be appropriately used depending on the kind of the semiconductor substrate, and the kind and the amount of the impurities to be removed. Examples of the component included in the composition for a buffing treatment include a water-soluble polymer such as polyvinyl alcohol, water as a dispersion medium, and an acid such as nitric acid.

In addition, in one embodiment of the buffing treatment, it is preferable that a semiconductor substrate is buffed using the cleaning liquid as the composition for a buffing treatment.

A polishing device, polishing conditions, and the like, which are used in the buffing treatment, can be appropriately selected from known devices and conditions according to the kind of the semiconductor substrate, the object to be removed, and the like. Examples of the buffing treatment include the treatments described in paragraphs [0085] to [0088] of WO2017/169539A, the contents of which are incorporated in the present specification.

[Cleaning Method for Semiconductor Substrate]

A cleaning method for a semiconductor substrate is not particularly limited as long as it includes a cleaning step of cleaning a semiconductor substrate, using the cleaning liquid.

The semiconductor substrate is preferably a semiconductor substrate that has been subjected to a CMP treatment.

The cleaning method for a semiconductor substrate also preferably includes a step of applying a diluted cleaning liquid obtained in the diluting step to the semiconductor substrate that has been subjected to a CMP treatment to carry out cleaning.

For example, the cleaning step of cleaning the semiconductor substrate using the cleaning liquid may appropriately employ a mode that is generally carried out in this field, such as scrub cleaning in which a cleaning member such as a brush is physically brought into contact with a surface of the semiconductor substrate while supplying a cleaning liquid to a semiconductor substrate, thereby removing residues; an immersion method in which a semiconductor substrate is immersed in a cleaning liquid; a spinning (dropping) method in which a cleaning liquid is dropped while rotating a semiconductor substrate; or a spray method in which a cleaning liquid is sprayed, as long as it is a known method that is carried out on a semiconductor substrate that has been subjected to a CMP treatment. In the immersion type cleaning, it is preferable to subject the cleaning liquid in which the semiconductor substrate is immersed to an ultrasonic treatment from the viewpoint that impurities remaining on the surface of the semiconductor substrate can be further reduced.

The cleaning step may be carried out only once or twice or more. In a case of carrying out cleaning two or more times, the same method may be repeated, or different methods may be combined.

The cleaning method for a semiconductor substrate may be any one of a single-wafer method or a batch method.

The single-wafer method is generally a method of treating semiconductor substrates one by one, and the batch method is generally a method of treating a plurality of semiconductor substrates at the same time.

The temperature of the cleaning liquid that is used for cleaning a semiconductor substrate is not particularly limited as long as it is a temperature that is usually used in this field. Generally, the cleaning is carried out at room temperature (about 25° C.), but any temperature can be selected in order to improve the cleaning properties and suppress the damage resistance to a member. For example, the temperature of the cleaning liquid is preferably 10° C. to 60° C., and more preferably 15° C. to 50° C.

The pH of the cleaning liquid is preferably the suitable aspect of the pH of the cleaning liquid described above. The pH of the diluted cleaning liquid is also preferably the suitable aspect of the pH of the cleaning liquid described above.

The cleaning time in the cleaning of the semiconductor substrate can be appropriately changed depending on the kind, content, and the like of the component contained in the cleaning liquid. Practically, the heating time is preferably 10 to 120 seconds, more preferably 20 to 90 seconds, and still more preferably 30 to 60 seconds.

The supply amount (the supply rate) of the cleaning liquid in the cleaning step for the semiconductor substrate is preferably 50 to 5,000 mL/min and more preferably 500 to 2,000 mL/min.

In the cleaning of the semiconductor substrate, a mechanical stirring method may be used in order to further improve the cleaning ability of the cleaning liquid.

Examples of the mechanical stirring method include a method of circulating a cleaning liquid on a semiconductor substrate, a method of flowing or spraying a cleaning liquid on a semiconductor substrate, and a method of stirring a cleaning liquid with an ultrasonic or a megasonic.

After cleaning the semiconductor substrate, a step of rinsing and cleaning the semiconductor substrate with a solvent (hereinafter, also referred to as a “rinsing step”) may be carried out.

The rinsing step is preferably a step which is carried out continuously subsequently after the cleaning step for the semiconductor substrate and in which rinsing is carried out with a rinsing solvent (a rinsing liquid) over 5 to 300 seconds. The rinsing step may be carried out using the above-described mechanical stirring method.

Examples of the rinsing solvent include water (preferably deionized (DI) water), methanol, ethanol, isopropyl alcohol, N-methylpyrrolidinone, γ-butyrolactone, dimethyl sulfoxide, ethyl lactate, and propylene glycol monomethyl ether acetate. In addition, an aqueous rinsing liquid having a pH of more than 8.0 (an aqueous ammonium hydroxide that has been diluted, or the like) may be used.

As a method of bringing the rinsing solvent into contact with the semiconductor substrate, the above-described method of bringing the cleaning liquid into contact with the semiconductor substrate can be similarly applied.

In addition, after the rinsing step, a drying step of drying the semiconductor substrate may be carried out.

Examples of the drying method include a spin drying method, a method of flowing a dry gas onto a semiconductor substrate, a method of heating a substrate by a heating means such as a hot plate and an infrared lamp, a Marangoni drying method, a Rotagoni drying method, an isopropyl alcohol (IPA) drying method, and a method of any combinations of these methods.

### EXAMPLES

Hereinbelow, the present invention will be described in more detail with reference to Examples. The materials, the amounts of the materials to be used, the proportions, and the like shown in the Examples below may be modified as appropriate as long as the modifications do not depart from the spirit of the present invention. Accordingly, the scope of the present invention should not be construed as being limited to Examples shown below.

In the following Examples, the pH of the cleaning liquid was measured at 25° C. using a pH meter (manufactured by HORIBA, Ltd., model “F-74”) in accordance with JIS Z8802-1984.

In addition, in the production of cleaning liquids of Examples and Comparative Examples, handling of the container, and preparation, filling, storage, and analytical measurement of the cleaning liquids were all carried out in a clean room satisfying a level of ISO Class 2 or lower.

[Raw Material for Cleaning Liquid]

The following compounds were used to produce a cleaning liquid. It is noted that as various components used in Examples, those all classified into a semiconductor grade or a high-purity grade equivalent thereto were used.

[Compound A]

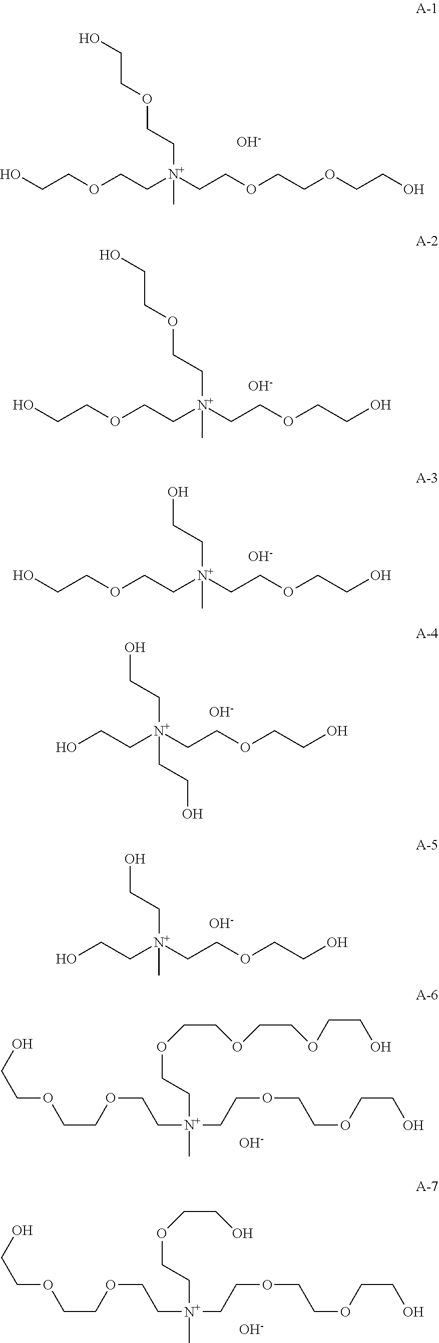

[Compound B]
B-1: Tris(2-hydroxyethyl)methylammonium hydroxide
B-2: Tetra (2-hydroxyethyl)ammonium hydroxide
B-3: Dimethylbis(2-hydroxyethyl)ammonium hydroxide
B-4: 2-hydroxyethyltrimethylammonium hydroxide (choline)
B-5: Tetramethylammonium hydroxide
B-6: Tetraethylammonium hydroxide
B-7: Cetyltrimethylammonium bromide
B-8: Ethyltrimethylammonium hydroxide

[Tertiary Amine]
Polyoxyethylene laurylamine (manufactured by AOKI OIL INDUSTRIAL Co., Ltd., BLAUNON L-210, EO-added molar number: 10)
MDEA: N-methyldiethanolamine
DMAMP: 2-(dimethylamino)-2-methyl-1-propanol
DABCO: 1,4-diazabicyclo[2.2.2]octane

[Other Components]

<Purine Compound>
Xanthine
Hypoxanthine
Adenine
Caffeine
Guanine

<Chelating Agent>
Tartaric acid
Citric acid
Malic acid
Phosphoric acid

<Others>
Imidazole
Benzotriazole
Polyethylene glycol (manufactured by Fujifilm Wako Pure Chemical Corporation, polyethylene glycol 6,000)
Dodecylbenzenesulfonic acid
Carboxybetaine: Carboxybetaine-type amphoteric surfactant (manufactured by Kao Corporation, AMPHITOL 20BS)
AMP: 2-amino-2-methyl-1-propanol
γ-cyclodextrin
Iodic acid
Periodic acid
Cysteine
Cysteamine
Thioglycerol
Mercaptopropionic acid
3-mercapto-1,2,4-triazole
Erythritol
Thiourea
1,3,4-thiadiazole
Cystine
Ethylene glycol
Propylene glycol
2-Butoxyethanol
Monoethanolamine
Uracil
1,2,4-triazole

[pH Adjusting Agent and Ultrapure Water]

In addition, in the manufacturing step of the cleaning liquid in present Examples, potassium hydroxide or sulfuric acid, and commercially available ultrapure water (manufactured by FUJIFILM Wako Pure Chemical Corporation) were used as the pH adjusting agent.

In the cleaning liquid, the remaining component (the remainder) that is neither a component specified as a component of the cleaning liquid in the table nor the pH adjusting agent is ultrapure water.

[Production of Cleaning Liquid]

Next, a method for producing the cleaning liquid will be described by taking Example 1 as an example.

An amount of the compound A-1 was added to ultrapure water so that the cleaning liquid to be finally obtained had the formulation shown in the table below, and then a pH adjusting agent was added thereto so that the pH of the cleaning liquid to be prepared was 13.0. The obtained mixed solution was sufficiently stirred to obtain a cleaning liquid of Example 1.

According to the production method of Example 1, a cleaning liquid of each Example or each Comparative Example, having the composition shown in the table below, was individually produced. It is noted that the content of the pH adjusting agent in each cleaning liquid was 0.1% to 3.0% by mass with respect to the total mass of each cleaning liquid.

[Evaluation of Cleaning Performance (Organic Impurities)]

The cleaning liquid produced by the above-described method was used to evaluate the cleaning performance of organic impurities in a case where a metal film was subjected to chemical mechanical polishing.

In the test of each Example and each Comparative Example, 10 mL of the cleaning liquid of each Example and each Comparative Example was aliquoted and diluted 100-fold by mass ratio with ultrapure water to prepare a sample of the diluted cleaning liquid.

Using FREX300S-II (a polishing device, manufactured by Ebara Corporation) and using BSL8872 (trade name, manufactured by FUJIFILM Electronic Materials Co., Ltd.) as a polishing liquid, a wafer (diameter: 12 inches) having a BD1 film (a Low-k film) on the surface was polished under the conditions of a polishing pressure of 2.0 psi and a polishing liquid supply rate of 0.28 mL/(min cm²), and a polishing time of 60 seconds.

Then, scrub cleaning was carried out for 60 seconds using the sample of each diluted cleaning liquid adjusted to room temperature (23° C.), and a drying treatment was carried out. A defect detection device (ComPlus-II, manufactured by Applied Materials, Inc.) was used to measure the number of detections of signal intensities corresponding to defects having a length of more than 0.1 m on the obtained polished surface of the wafer, each of the defects was measured with a scanning electron microscope (SEM), and the measurement target was specified by the energy dispersion type X-ray analysis (EDX) of the constitutional elements as necessary.

In this way, the number of defects based on the organic impurities on the polished surface of the wafer was determined.
8: The number of target defects is less than 1 piece/cm².
7: The number of target defects is 1 piece/cm² or more and less than 3 pieces/cm².
6: The number of target defects is 3 pieces/cm² or more and less than 5 pieces/cm².
5: The number of target defects is 5 pieces/cm² or more and less than 8 pieces/cm².
4: The number of target defects is 8 pieces/cm² or more and less than 10 pieces/cm².
3: The number of target defects is 10 pieces/cm² or more and less than 20 pieces/cm².
2: The number of target defects is 20 pieces/cm² or more and less than 30 pieces/cm².
1: The number of target defects is 30 pieces/cm² or more.

[Evaluation of Anticorrosion Properties (Copper)]

A copper wafer was placed in a container filled with the cleaning liquid of each Example or each Comparative Example and subjected to an immersion treatment at room temperature (25° C.) for 10 minutes. Then, the film thickness of the obtained wafer was measured, and the etching rate (EG-A) (Å/min) was determined from the difference in film thickness before and after the immersion treatment.

In addition, the etching rate (EG-B) (Å/min) was determined from the difference in film thickness before and after the immersion treatment by the same procedure as described above except that the cleaning liquid of each Example or each Comparative Example was replaced with deionized water (DIW), and the anticorrosion properties (copper) were evaluated by comparing EG-A and EG-B.
6: EG-A is 0.3 or less of EG-B.
5: EG-A is more than 0.3 and 0.5 or less of EG-B.
4: EG-A is more than 0.5 and 0.9 or less of EG-B.
3: EG-A is more than 0.9 and 1.1 or less of EG-B.
2: EG-A is more than 1.1 and less than 1.5 of EG-B.
1: EG-A is 1.5 or more of EG-B

In a state where the cleaning liquid was a diluted cleaning liquid after having been diluted by 100 times by mass, the pH of the cleaning liquid of Example 53 was 10.7, the pH of the cleaning liquid of Example 54 was 8.6, and the pH of the cleaning liquid of Example 55 was 6.8.

It is noted that in a state where the cleaning liquid was a diluted cleaning liquid after having been diluted by 100 times by mass, the pH of each of cleaning liquids other than Examples above was 10.9 to 11.6.

[Results]

In the table, the column of “Content (% by mass” indicates the content (% by mass) of each component with respect to the total mass of the cleaning liquid.

The column of “A/B” indicates the mass ratio of the content of the compound A to the content of the compound B (content of compound A/content of compound B).

The column of “A/D” indicates the mass ratio of the content of the compound A to the content of the purine compound (content of compound A/content of purine compound).

The numerical value in the column of “pH” indicates the pH of the cleaning liquid at 25° C. before 100-fold dilution, which is measured with the pH meter. That is, the pH of the undiluted cleaning liquid is shown.

TABLE 1

| | Cleaning liquid | | | | | |
|---|---|---|---|---|---|---|
| | Compound A | | Compound B | | Tertiary amine (C) | |
| | | Content | | Content | | Content |
| | Kind | (% by mass) | Kind | (% by mass) | Kind | (% by mass) |
| Comparative | | | B-6 | 5.0 | | |
| Example 1 | | | | | | |
| Comparative | | | B-1 | 5.0 | | |
| Example 2 | | | | | | |
| Comparative | | | B-1 | 5.0 | Polyoxyethylene | 5.0 |
| Example 3 | | | | | laurylamine | |
| Comparative | | | | | Polyoxyethylene | 5.0 |
| Example 4 | | | | | laurylamine | |
| Comparative | | | | | MDEA | 5.0 |
| Example 5 | | | | | | |
| Comparative | | | B-1 | 5.0 | MDEA | 5.0 |
| Example 6 | | | | | | |
| Example 1 | A-1 | 5.0 | | | | |
| Example 2 | A-1 | 1.0 | | | | |
| Example 3 | A-2 | 1.0 | | | | |
| Example 4 | A-3 | 1.0 | | | | |
| Example 5 | A-4 | 1.0 | | | | |
| Example 6 | A-5 | 1.0 | | | | |
| Example 7 | A-6 | 1.0 | | | | |
| Example 8 | A-7 | 1.0 | | | | |
| Example 9 | A-1 | 1.0 | B-1 | 20.0 | | |
| Example 10 | A-1 | 1.0 | B-1 | 10.0 | | |
| Example 11 | A-1 | 1.0 | B-1 | 7.0 | | |
| Example 12 | A-1 | 1.0 | B-1 | 5.0 | | |
| Example 13 | A-1 | 1.0 | B-1 | 4.0 | | |
| Example 14 | A-1 | 1.0 | B-1 | 3.0 | | |
| Example 15 | A-1/A-2 | 1.0/1.0 | B-1 | 5.0 | | |
| Example 16 | A-1/A-2/A-3 | 1.0/1.0/1.0 | B-1 | 5.0 | | |
| Example 17 | A-1/A-2/A-3/ | 1.0/1.0/1.0/ | B-1 | 5.0 | | |
| | A-4/A-5 | 1.0/1.0 | | | | |
| Example 18 | A-1/A-2/A-3/ | 1.0/1.0/1.0/ | B-1 | 5.0 | | |
| | A-4/A-5/A-6/A-7 | 1.0/1.0/1.0/1.0 | | | | |
| Example 19 | A-1 | 1.0 | B-2 | 5.0 | | |
| Example 20 | A-1 | 1.0 | B-3 | 5.0 | | |
| Example 21 | A-1 | 1.0 | B-4 | 5.0 | | |
| Example 22 | A-1 | 1.0 | B-1 | 5.0 | | |
| Example 23 | A-1 | 1.0 | B-1 | 5.0 | | |
| Example 24 | A-1 | 1.0 | B-1 | 5.0 | | |
| Example 25 | A-1 | 1.0 | B-1 | 5.0 | | |

| | | | | | | Evaluation result | |
|---|---|---|---|---|---|---|---|
| | Cleaning liquid | | | | | Cleaning | |
| | Another compound | | | | | performance | Anticorrosion |
| | | Content | | | | (organic | properties |
| | Kind | (% by mass) | A/B | A/D | pH | impurities) | (copper) |
| Comparative | | | | | 13.0 | 3 | 1 |
| Example 1 | | | | | | | |
| Comparative | | | | | 13.0 | 3 | 1 |
| Example 2 | | | | | | | |
| Comparative | | | | | 13.0 | 3 | 2 |
| Example 3 | | | | | | | |
| Comparative | | | | | 13.0 | 2 | 2 |
| Example 4 | | | | | | | |
| Comparative | | | | | 13.0 | 2 | 2 |
| Example 5 | | | | | | | |
| Comparative | | | | | 13.0 | 3 | 2 |
| Example 6 | | | | | | | |
| Example 1 | | | | | 13.0 | 6 | 1 |
| Example 2 | | | | | 13.0 | 7 | 1 |
| Example 3 | | | | | 13.0 | 7 | 1 |
| Example 4 | | | | | 13.0 | 7 | 1 |
| Example 5 | | | | | 13.0 | 8 | 1 |
| Example 6 | | | | | 13.0 | 8 | 1 |
| Example 7 | | | | | 13.0 | 7 | 1 |
| Example 8 | | | | | 13.0 | 7 | 1 |
| Example 9 | | | 0.05 | | 13.0 | 6 | 1 |
| Example 10 | | | 0.10 | | 13.0 | 6 | 1 |
| Example 11 | | | 0.14 | | 13.0 | 7 | 1 |
| Example 12 | | | 0.20 | | 13.0 | 8 | 1 |
| Example 13 | | | 0.25 | | 13.0 | 8 | 1 |
| Example 14 | | | 0.33 | | 13.0 | 8 | 1 |
| Example 15 | | | | | 13.0 | 7 | 1 |
| Example 16 | | | | | 13.0 | 7 | 1 |
| Example 17 | | | | | 13.0 | 7 | 1 |
| Example 18 | | | | | 13.0 | 6 | 1 |
| Example 19 | | | 0.20 | | 13.0 | 7 | 1 |
| Example 20 | | | 0.20 | | 13.0 | 7 | 1 |
| Example 21 | | | 0.20 | | 13.0 | 6 | 1 |
| Example 22 | Xanthine | 0.2 | 0.20 | 5.0 | 13.0 | 8 | 4 |
| Example 23 | Xanthine | 2.0 | 0.20 | 0.5 | 13.0 | 8 | 5 |
| Example 24 | Xanthine | 5.0 | 0.20 | 0.2 | 13.0 | 8 | 6 |
| Example 25 | Hypoxanthine | 0.2 | 0.20 | 5.0 | 13.0 | 8 | 4 |

TABLE 2

| | Cleaning liquid | | | | | | |
|---|---|---|---|---|---|---|---|
| | Compound A | | Compound B | | Tertiary amine (C) | | |
| | | Content | | Content | | Content | Another compound |
| | Kind | (% by mass) | Kind | (% by mass) | Kind | (% by mass) | Kind |
| Example 26 | A-1 | 1.0 | | | MDEA | 5.0 | |
| Example 27 | A-1 | 1.0 | | | MDEA | 1.0 | |
| Example 28 | A-1 | 1.0 | | | MDEA | 0.1 | |
| Example 29 | A-1 | 1.0 | B-1 | 5.0 | MDEA | 5.0 | |
| Example 30 | A-1 | 1.0 | B-1 | 5.0 | MDEA | 25.0 | |
| Example 31 | A-1 | 1.0 | B-1 | 5.0 | MDEA | 70.0 | |
| Example 32 | A-1 | 1.0 | B-1 | 5.0 | | | AMP |
| Example 33 | A-1 | 1.0 | B-1 | 5.0 | DMAMP | 5.0 | |
| Example 34 | A-1 | 1.0 | B-1 | 5.0 | DABCO | 5.0 | |
| Example 35 | A-1 | 1.0 | B-1 | 5.0 | MDEA | 5.0 | |
| Example 36 | A-1 | 1.0 | B-1 | 8.0 | MDEA | 5.0 | |
| Example 37 | A-1 | 1.0 | B-1 | 15.0 | MDEA | 5.0 | |
| Example 38 | A-1 | 1.0 | B-5 | 5.0 | MDEA | 5.0 | |
| Example 39 | A-1 | 1.0 | B-6 | 5.0 | MDEA | 5.0 | |
| Example 40 | A-1 | 1.0 | B-3 | 5.0 | MDEA | 5.0 | |
| Example 41 | A-1 | 1.0 | B-1 | 5.0 | | | Tartaric acid |
| Example 42 | A-1 | 1.0 | B-1 | 5.0 | | | Tartaric acid |
| Example 43 | A-1 | 1.0 | B-1 | 5.0 | | | Tartaric acid |
| Example 44 | A-1 | 1.0 | B-1 | 5.0 | | | Citric acid |
| Example 45 | A-1 | 1.0 | B-1 | 5.0 | | | Malic acid |
| Example 46 | A-1 | 1.0 | B-1 | 5.0 | | | Imidazole |
| Example 47 | A-1 | 1.0 | B-1 | 5.0 | | | Imidazole |
| Example 48 | A-1 | 1.0 | B-1 | 5.0 | | | Imidazole |
| Example 49 | A-1 | 1.0 | B-1 | 5.0 | | | Polyethylene glycol |
| Example 50 | A-1 | 1.0 | B-1 | 5.0 | | | Dodecylbenzenesulfonic |
| | | | | | | | acid |
| Example 51 | A-1 | 1.0 | B-1/B-7 | 5.0/1.0 | | | |
| Example 52 | A-1 | 1.0 | B-1 | 5.0 | | | Carboxybetaine |
| Example 53 | A-1 | 1.0 | B-1 | 5.0 | | | |
| Example 54 | A-1 | 1.0 | B-1 | 5.0 | | | |
| Example 55 | A-1 | 1.0 | B-1 | 5.0 | | | |
| Example 56 | A-1 | 5.0 | B-1 | 5.0 | | | |

| | | | | | Evaluation result | |
|---|---|---|---|---|---|---|
| | Cleaning liquid | | | | Cleaning | |
| | Another compound | | | | performance | Anticorrosion |
| | Content | | | | (organic | properties |
| | (% by mass) | A/B | A/D | pH | impurities) | (copper) |
| Example 26 | | | | 13.0 | 7 | 3 |
| Example 27 | | | | 13.0 | 7 | 3 |
| Example 28 | | | | 13.0 | 6 | 2 |
| Example 29 | | 0.20 | | 13.0 | 8 | 3 |
| Example 30 | | 0.20 | | 13.0 | 8 | 3 |
| Example 31 | | 0.20 | | 13.0 | 6 | 2 |
| Example 32 | 5.0 | 0.20 | | 13.0 | 8 | 3 |
| Example 33 | | 0.20 | | 13.0 | 8 | 3 |
| Example 34 | | 0.20 | | 13.0 | 8 | 2 |
| Example 35 | | 0.20 | | 13.0 | 8 | 3 |
| Example 36 | | 0.13 | | 13.0 | 7 | 3 |
| Example 37 | | 0.07 | | 13.0 | 6 | 2 |
| Example 38 | | 0.20 | | 13.0 | 7 | 3 |
| Example 39 | | 0.20 | | 13.0 | 7 | 3 |
| Example 40 | | 0.20 | | 13.0 | 7 | 3 |
| Example 41 | 0.5 | 0.20 | | 13.0 | 8 | 2 |
| Example 42 | 4.5 | 0.20 | | 13.0 | 8 | 2 |
| Example 43 | 7.0 | 0.20 | | 13.0 | 8 | 2 |
| Example 44 | 0.5 | 0.20 | | 13.0 | 8 | 3 |
| Example 45 | 0.5 | 0.20 | | 13.0 | 8 | 3 |
| Example 46 | 0.5 | 0.20 | | 13.0 | 8 | 4 |
| Example 47 | 4.5 | 0.20 | | 13.0 | 8 | 5 |
| Example 48 | 7.0 | 0.20 | | 13.0 | 8 | 6 |
| Example 49 | 1.0 | 0.20 | | 13.0 | 8 | 4 |
| Example 50 | 1.0 | 0.20 | | 13.0 | 8 | 4 |
| Example 51 | | 0.17 | | 13.0 | 8 | 3 |
| Example 52 | 1.0 | 0.20 | | 13.0 | 8 | 4 |
| Example 53 | | 0.20 | | 12.0 | 7 | 1 |
| Example 54 | | 0.20 | | 9.0 | 7 | 1 |
| Example 55 | | 0.20 | | 7.0 | 6 | 1 |
| Example 56 | | 1.00 | | 13.0 | 7 | 1 |

TABLE 3

| | Cleaning liquid | | | | | | |
|---|---|---|---|---|---|---|---|
| | Compound A | | Compound B | | Tertiary amine (C) | | |
| | | Content | | Content | | Content | Another compound |
| | Kind | (% by mass) | Kind | (% by mass | Kind | (% by mass) | Kind |
| Example 57 | A-1 | 7.0 | B-1 | 5.0 | | | |
| Example 58 | A-1 | 9.0 | B-1 | 5.0 | | | |
| Example 59 | A-1 | 1.0 | B-1 | 5.0 | | | Xanthine/adenine |
| Example 60 | A-1 | 1.0 | B-1 | 5.0 | | | Xanthine/hypoxanthine |
| Example 61 | A-1 | 1.0 | B-1 | 5.0 | | | Xanthine/benzotriazole |
| Example 62 | A-1 | 1.0 | B-1 | 5.0 | MDEA | 5.0 | AMP |
| Example 63 | A-1 | 1.0 | B-1 | 5.0 | MDEA | 5.0 | Tartaric acid/citric acid |
| Example 64 | A-1 | 1.0 | B-1 | 5.0 | MDEA | 5.0 | Tartaric acid/phosphoric acid |
| Example 65 | A-1 | 1.0 | B-1 | 5.0 | MDEA | 5.0 | γ-cyclodextrin |
| Example 66 | A-1 | 1.0 | B-1 | 5.0 | MDEA | 5.0 | Iodic acid |
| Example 67 | A-1 | 1.0 | B-1 | 5.0 | MDEA | 5.0 | Periodic acid |
| Example 68 | A-1 | 1.0 | B-1 | 5.0 | MDEA | 5.0 | Periodic acid/Xanthine |
| Example 69 | A-1 | 1.0 | B-1 | 5.0 | MDEA | 5.0 | Xanthine |
| Example 70 | A-1 | 1.0 | B-1 | 5.0 | MDEA | 5.0 | Tartaric acid/Xanthine |
| Example 71 | A-1/A-2/A-3/ | 1.0/1.0/1.0/ | B-1 | 5.0 | MDEA | 5.0 | Tartaric acid/Xanthine |
| | A-4/A-5/A-6/A-7 | 1.0/1.0/1.0/1.0 | | | | | |
| Example 72 | A-1 | 1.0 | B-8 | 5.0 | | | Cystine |
| Example 73 | A-1 | 1.0 | B-8 | 5.0 | | | Cystine |
| Example 74 | A-1 | 1.0 | B-8 | 5.0 | | | Thioglycerol |
| Example 75 | A-1 | 1.0 | B-8 | 5.0 | | | Mercaptopropionic acid |
| Example 76 | A-1 | 1.0 | B-8 | 5.0 | | | 3-mercapto-1,2,4-triazole |
| Example 77 | A-1 | 1.0 | B-8 | 5.0 | | | Erythritol |
| Example 78 | A-1 | 1.0 | B-8 | 5.0 | | | Thiourea |
| Example 79 | A-1 | 1.0 | B-8 | 5.0 | | | 1,3,4-thiadiazole |
| Example 80 | A-1 | 1.0 | B-8 | 5.0 | | | cystine |
| Example 81 | A-1 | 1.0 | B-8 | 5.0 | | | Cysteine/cystine |
| Example 82 | A-1 | 1.0 | B-8 | 5.0 | | | Ethylene glycol |
| Example 83 | A-1 | 1.0 | B-8 | 5.0 | | | Propylene glycol |
| Example 84 | A-1 | 1.0 | B-8 | 5.0 | | | 2-Butoxyethanol |
| Example 85 | A-1 | 1.0 | B-8 | 5.0 | | | Monoethanolamine |
| Example 86 | A-1 | 1.0 | B-8 | 5.0 | | | Ethylene glycol/cystine |

| | | | | | Evaluation result | |
|---|---|---|---|---|---|---|
| | Cleaning liquid | | | | Cleaning | |
| | Another compound | | | | performance | Anticorrosion |
| | Content | | | | (organic | properties |
| | (% by mass) | A/B | A/D | PH | impurities) | (copper) |
| Example 57 | | 1.40 | | 13.0 | 6 | 1 |
| Example 58 | | 1.80 | | 13.0 | 6 | 1 |
| Example 59 | 0.2/0.2 | 0.20 | 2.5 | 13.0 | 8 | 4 |
| Example 60 | 0.2/0.2 | 0.20 | 2.5 | 13.0 | 8 | 4 |
| Example 61 | 0.2/0.2 | 0.20 | 5.0 | 13.0 | 8 | 4 |
| Example 62 | 5.0 | 0.20 | | 13.0 | 8 | 3 |
| Example 63 | 0.5/0.5 | 0.20 | | 13.0 | 8 | 4 |
| Example 64 | 0.5/0.5 | 0.20 | | 13.0 | 8 | 4 |
| Example 65 | 0.5 | 0.20 | | 13.0 | 8 | 3 |
| Example 66 | 0.5 | 0.20 | | 13.0 | 8 | 2 |
| Example 67 | 0.5 | 0.20 | | 13.0 | 8 | 2 |
| Example 68 | 0.5/0.2 | 0.20 | 5.0 | 13.0 | 8 | 5 |
| Example 69 | 0.2 | 0.20 | 5.0 | 13.0 | 8 | 5 |
| Example 70 | 0.5/0.2 | 0.20 | 5.0 | 13.0 | 8 | 5 |
| Example 71 | 0.5/0.2 | 1.40 | 35.0 | 13.0 | 6 | 5 |
| Example 72 | 1.0 | 0.20 | | 13.0 | 6 | 1 |
| Example 73 | 1.0 | 0.20 | | 13.0 | 6 | 1 |
| Example 74 | 1.0 | 0.20 | | 13.0 | 6 | 1 |
| Example 75 | 1.0 | 0.20 | | 13.0 | 6 | 1 |
| Example 76 | 1.0 | 0.20 | | 13.0 | 6 | 1 |
| Example 77 | 1.0 | 0.20 | | 13.0 | 6 | 1 |
| Example 78 | 1.0 | 0.20 | | 13.0 | 6 | 1 |
| Example 79 | 1.0 | 0.20 | | 13.0 | 6 | 1 |
| Example 80 | 1.0 | 0.20 | | 13.0 | 6 | 1 |
| Example 81 | 0.5/0.5 | 0.20 | | 13.0 | 6 | 1 |
| Example 82 | 1.0 | 0.20 | | 13.0 | 6 | 1 |
| Example 83 | 1.0 | 0.20 | | 13.0 | 6 | 1 |
| Example 84 | 1.0 | 0.20 | | 13.0 | 6 | 1 |
| Example 85 | 1.0 | 0.20 | | 13.0 | 6 | 1 |
| Example 86 | 1.0/1.0 | 0.20 | | 13.0 | 6 | 1 |

TABLE 4

| | Cleaning liquid | | | | | | |
|---|---|---|---|---|---|---|---|
| | Compound A | | Compound B | | Tertiary amine (C) | | |
| | | Content | | Content | | Content | Another compound |
| | Kind | (% by mass) | Kind | (% by mass) | Kind | (% by mass) | Kind |
| Example 87 | A-1 | 1.0 | B-8 | 5.0 | | | Propylene glycol/cysteine |
| Example 88 | A-1 | 1.0 | B-8 | 5.0 | | | 2-Butoxyethanol/cysteine |
| Example 89 | A-1 | 1.0 | B-8 | 5.0 | | | Monoethanolamine/cysteine |
| Example 90 | A-1 | 1.0 | B-8 | 5.0 | MDEA | 5.0 | Cysteine |
| Example 91 | A-1 | 1.0 | B-8 | 5.0 | | | Xanthine/cysteine |
| Example 92 | A-1 | 1.0 | B-8 | 5.0 | | | Adenine/cysteine |
| Example 93 | A-1 | 1.0 | B-8 | 5.0 | | | Caffeine/cysteine |
| Example 94 | A-1 | 1.0 | B-8 | 5.0 | | | Uracil/cysteine |
| Example 95 | A-1 | 1.0 | B-8 | 5.0 | | | 1,2,4-triazole/cysteine |
| Example 96 | A-1 | 1.0 | B-8 | 5.0 | | | Xanthine/propylene glycol |
| Example 97 | A-1 | 1.0 | B-8 | 5.0 | | | Xanthine/propylene glycol/cysteine |
| Example 98 | A-1 | 1.0 | B-8 | 5.0 | | | Adenine/propylene glycol/cysteine |
| Example 99 | A-1 | 1.0 | B-8 | 5.0 | | | Guanine/propylene glycol/cysteine |
| Example 100 | A-1 | 1.0 | B-8 | 5.0 | | | Caffeine/propylene glycol/cysteine |
| Example 101 | A-1 | 1.0 | B-8 | 5.0 | | | Uracil/propylene glycol/cysteine |
| Example 102 | A-1 | 1.0 | B-8 | 5.0 | | | 1,2,4-triazole/propylene glycol/cysteine |
| Example 103 | A-1 | 1.0 | B-8 | 5.0 | | | Xanthine/propylene glycol/cysteine/cystine |

| | | | | | Evaluation result | |
|---|---|---|---|---|---|---|
| | Cleaning liquid | | | | Cleaning | |
| | Another compound | | | | performance | Anticorrosion |
| | Content | | | | (organic | properties |
| | (% by mass) | A/B | A/D | pH | impurities) | (copper) |
| Example 87 | 1.0/1.0 | 0.20 | | 13.0 | 6 | 1 |
| Example 88 | 1.0/1.0 | 0.20 | | 13.0 | 6 | 1 |
| Example 89 | 1.0/1.0 | 0.20 | | 13.0 | 6 | 1 |
| Example 90 | 1.0/1.0 | 0.20 | | 13.0 | 6 | 5 |
| Example 91 | 0.5/1.0 | 0.20 | 2.0 | 13.0 | 6 | 5 |
| Example 92 | 0.5/1.0 | 0.20 | 2.0 | 13.0 | 6 | 5 |
| Example 93 | 0.5/1.0 | 0.20 | 2.0 | 13.0 | 6 | 5 |
| Example 94 | 0.5/1.0 | 0.20 | | 13.0 | 6 | 5 |
| Example 95 | 0.5/1.0 | 0.20 | | 13.0 | 6 | 5 |
| Example 96 | 0.5/1.0 | 0.20 | 2.0 | 13.0 | 6 | 5 |
| Example 97 | 0.5/1.0/1.0 | 0.20 | 2.0 | 13.0 | 6 | 5 |
| Example 98 | 0.5/1.0/1.0 | 0.20 | 2.0 | 13.0 | 6 | 5 |
| Example 99 | 0.5/1.0/1.0 | 0.20 | 2.0 | 13.0 | 6 | 5 |
| Example 100 | 0.5/1.0/1.0 | 0.20 | 2.0 | 13.0 | 6 | 5 |
| Example 101 | 0.5/1.0/1.0 | 0.20 | | 13.0 | 6 | 5 |
| Example 102 | 0.5/1.0/1.0 | 0.20 | | 13.0 | 6 | 5 |
| Example 103 | 0.5/1.0/0.5/0.5 | 0.20 | 2.0 | 13.0 | 6 | 5 |

From the above table, it has been confirmed that the cleaning liquid of the present invention is excellent in cleaning performance of organic impurities.

It has been confirmed that in a case where the molecular weight of the compound A is 200 to 250, the effect of the present invention is more excellent (the comparison among Examples 2 to 8).

It has been confirmed that in a case where the content of the compound A is 0.1% to 6.0% by mass with respect to the total mass of the cleaning liquid, the effect of the present invention is more excellent, and it has been confirmed that in a case where the content of the compound A is 0.5% to 4.9% by mass with respect to the total mass of the cleaning liquid, the effect of the present invention is still more excellent (the comparison among Examples 1 to 2, 12, 15 to 18, 56 to 58, and 71).

It has been confirmed that in a case where the content of the compound B is 0.05% to 9.0% by mass with respect to the total mass of the cleaning liquid, the effect of the present invention is more excellent, and it has been confirmed that in a case where the content of the compound B is 1.0% to 5.0% by mass with respect to the total mass of the cleaning liquid, the effect of the present invention is still more excellent (Examples 9 to 14, 29, and 36 to 37).

It has been confirmed that in a case where the molecular weight of the compound B is 120 to 200, the effect of the present invention is more excellent, and it has been confirmed that in a case where the molecular weight of the compound B is 150 to 170, the effect of the present invention is still more excellent, and (the comparison among Examples 12, 19-21, 29, and 38 to 40).

Further, it has been confirmed that in a case where the tertiary amine is contained, the anticorrosion properties are more excellent, and it has been confirmed that in a case where the content of the tertiary amine is 0.5% to 65.0% by mass with respect to the total mass of the cleaning liquid, the anticorrosion properties are still more excellent (the comparison among Examples 2 and 26 to 31).

Further, it has been confirmed that in a case where the anticorrosion agent is contained, the anticorrosion properties are more excellent (the comparison among Examples 12, 22 to 25, 46 to 48, and the like).

It has been confirmed that in a case where the content of the purine compound is 0.1% to 8.0% by mass with respect to the total mass of the cleaning liquid, the anticorrosion properties are more excellent, and it has been confirmed that in a case where the content of the purine compound is 4.0% to 8.0% by mass with respect to the total mass of the cleaning liquid, the anticorrosion properties are still more excellent (the comparison among Examples 22 to 25, 59 to 61, and the like).

It has been confirmed that in a case where the content of the azole compound is 1.0% to 10.0% by mass with respect to the total mass of the cleaning liquid, the anticorrosion properties are more excellent, and It has been confirmed that in a case where the content of the azole compound is 5.0% to 8.0% by mass with respect to the total mass of the cleaning liquid, the anticorrosion properties are still more excellent (Examples 46 to 48, and the like).

Further, it has been confirmed that in a case where the other amine is contained, the anticorrosion properties are more excellent (the comparison between Examples 12 and 32).

Further, it has been confirmed that in a case where the chelating agent is contained, the anticorrosion properties are more excellent, and it has been confirmed that in a case where citric acid, malic acid, or phosphoric acid is contained, the anticorrosion properties are still more excellent (Examples 41 to 45 and 63 to 64).

It has been confirmed that in a case where the pH of the cleaning liquid is 8.0 to 13.0, the effect of the present invention is more excellent (the comparison among Examples 12 and 53 to 55).

What is claimed is:

1. A cleaning liquid for a semiconductor substrate, which is used for cleaning a semiconductor substrate, the cleaning liquid comprising:
a compound represented by Formula (A), 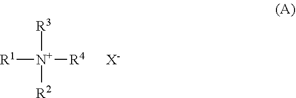
in Formula (A), R¹ to R⁴ each independently represent a substituent, at least one of R¹, . . . , or R⁴ represents a group represented by *—(R⁵—O)ₙ—H,
R⁵ represents an alkylene group, n represents an integer of 2 or more, * represents a bonding position, and X⁻ represents an anion, here, among R¹ to R⁴, groups other than the group represented by *—(R⁵—O)ₙ—H may be bonded to each other to form a ring.

2. The cleaning liquid for a semiconductor substrate according to claim 1,
wherein the cleaning liquid contains two or more kinds of the compound represented by Formula (A).

3. The cleaning liquid for a semiconductor substrate according to claim 1,
wherein R⁵ represents an ethylene group.

4. The cleaning liquid for a semiconductor substrate according to claim 1,
wherein one of R¹ to R⁴ represents the group represented by *—(R⁵—O)ₙ—H.

5. The cleaning liquid for a semiconductor substrate according to claim 1,
wherein one of R¹ to R⁴ represents the group represented by *—(R⁵—O)ₙ—H, and remaining three of R¹ to R⁴ represent an alkyl group which may have a substituent.

6. The cleaning liquid for a semiconductor substrate according to claim 1,
wherein a content of the compound represented by Formula (A) is 0.1% by mass or more with respect to a total mass of components in the cleaning liquid for a semiconductor substrate excluding a solvent.

7. The cleaning liquid for a semiconductor substrate according to claim 1, further comprising:
a quaternary ammonium compound B which does not have the group represented by *—(R⁵—O)ₙ—H.

8. The cleaning liquid for a semiconductor substrate according to claim 7,
wherein a content of the quaternary ammonium compound B is 0.1% by mass or more with respect to a total mass of components in the cleaning liquid for a semiconductor substrate excluding a solvent.

9. The cleaning liquid for a semiconductor substrate according to claim 1, further comprising:
an anticorrosion agent.

10. The cleaning liquid for a semiconductor substrate according to claim 9,
wherein the anticorrosion agent includes a bicyclic heterocyclic compound.

11. The cleaning liquid for a semiconductor substrate according to claim 9,
wherein the anticorrosion agent includes a purine compound.

12. The cleaning liquid for a semiconductor substrate according to claim 9,
wherein the anticorrosion agent includes at least one selected from the group consisting of xanthine, hypoxanthine, and adenine.

13. The cleaning liquid for a semiconductor substrate according to claim 1, further comprising:
a tertiary amine.

14. The cleaning liquid for a semiconductor substrate according to claim 13,
wherein the tertiary amine includes a tertiary amino alcohol.

15. The cleaning liquid for a semiconductor substrate according to claim 13,
wherein the tertiary amine includes N-methyldiethanolamine.

16. The cleaning liquid for a semiconductor substrate according to claim 1, further comprising:
an organic acid
wherein the organic acid includes a dicarboxylic acid.

17. The cleaning liquid for a semiconductor substrate according to claim 1,
wherein a pH is 8.0 to 13.0.

18. The cleaning liquid for a semiconductor substrate according to claim 1, further comprising:
water,
wherein a content of the water is 60% by mass or more with respect to a total mass of the cleaning liquid for a semiconductor substrate.

19. The cleaning liquid for a semiconductor substrate according to claim 1,
wherein the cleaning liquid for a semiconductor substrate is used for cleaning a semiconductor substrate that has been subjected to a chemical mechanical polishing treatment.

20. A cleaning method for a semiconductor substrate, comprising:
a cleaning step of cleaning a semiconductor substrate that has been subjected to a chemical mechanical polishing treatment, by using the cleaning liquid for a semiconductor substrate according to claim 1.
